(19) United States
(12) Patent Application Publication
(10) Pub. No.: US 2025/0366194 A1
(43) Pub. Date: Nov. 27, 2025

(54) SEMICONDUCTOR DEVICES

(71) Applicant: SAMSUNG ELECTRONICS CO., LTD., Suwon-si (KR)

(72) Inventors: Donghoon Hwang, Suwon-si (KR); Hyojin Kim, Suwon-si (KR); Byungho Moon, Suwon-si (KR); Jaeho Jeon, Suwon-si (KR); Wonchang Lee, Suwon-si (KR)

(21) Appl. No.: 19/204,081

(22) Filed: May 9, 2025

(30) Foreign Application Priority Data
May 23, 2024 (KR) 10-2024-0066871

(51) Int. Cl. H10D 84/85; H10D 84/01

(52) U.S. Cl. CPC H10D 84/856; H10D 84/017; H10D 84/0186; H10D 84/0188; H10D 84/851

(57) ABSTRACT

A semiconductor device includes first and second transistors and a contact plug. The first transistor includes first channels, a first gate structure and a first source/drain layer. The first gate structure extends in a first direction, and covers upper and lower surfaces and opposite sidewalls in the first direction of the first channels. The first source/drain layer is at opposite sides of the first gate structure in a second direction. The second transistor includes second channels, a second gate structure and a second source/drain layer. The second gate structure extends in the second direction, and covers upper and lower surfaces and opposite sidewalls in the second direction of the second channels. The second source/drain layer is at opposite sides of the second gate structure in the first direction. The contact plug extends in the vertical direction and contacts an upper surface of the first source/drain layer.

### CROSS-REFERENCE TO RELATED APPLICATION

This application claims priority under 35 USC § 119 to Korean Patent Application No. 10-2024-0066871, filed on May 23, 2024 in the Korean Intellectual Property Office (KIPO), the contents of which are herein incorporated by reference in their entirety.

### BACKGROUND

In order to highly integrate a semiconductor device, a method of stacking a plurality of transistors in a vertical direction has been studied. In order to transfer electrical signals to a lower transistor, a contact plug connected to an upper wiring is needed to contact a source/drain layer or a gate electrode of the lower transistor, however, processes for forming the contact plug are not easy.

### SUMMARY

Some implementations of the present disclosure provide semiconductor devices having enhanced characteristics.

According to some implementations of the present disclosure, there is provided a semiconductor device. The semiconductor device may include a first transistor, a second transistor and a contact plug. The first transistor may include first channels, a first gate structure and a first source/drain layer. The first channels may be disposed on a substrate, and may be spaced apart from each other in a vertical direction substantially perpendicular to an upper surface of the substrate. The first gate structure may extend on the substrate in a first direction substantially parallel to the upper surface of the substrate, and may cover upper and lower surfaces and opposite sidewalls in the first direction of the first channels. The first source/drain layer may be disposed at opposite sides of the first gate structure in a second direction substantially parallel to the upper surface of the substrate and substantially perpendicular to the first direction. The second transistor may include second channels, a second gate structure and a second source/drain layer. The second channels may be disposed on the first channels, and may be spaced apart from each other in the vertical direction. The second gate structure may extend on the substrate in the second direction, and may cover upper and lower surfaces and opposite sidewalls in the second direction of the second channels. The second source/drain layer may be disposed at opposite sides of the second gate structure in the first direction. The contact plug may extend in the vertical direction and contact an upper surface of the first source/drain layer.

According to some implementations of the present disclosure, there is provided a semiconductor device. The semiconductor device may include first channels, a first gate structure, a first source/drain layer, second channels, a second gate structure, a second source/drain layer and a contact plug. The first channels may be disposed on a substrate, and may be spaced apart from each other in a vertical direction substantially perpendicular to an upper surface of the substrate. The first gate structure may extend on the substrate in a first direction substantially parallel to the upper surface of the substrate, and may cover upper and lower surfaces and opposite sidewalls in the first direction of the first channels. The first source/drain layer may be disposed at opposite sides of the first gate structure in a second direction substantially parallel to the upper surface of the substrate and substantially perpendicular to the first direction. The second channels may be disposed on the first channels, and may be spaced apart from each other in the vertical direction. The second gate structure may extend on the substrate in the second direction, and may cover upper and lower surfaces and opposite sidewalls in the second direction of the second channels. The second source/drain layer may be disposed at opposite sides of the second gate structure in the first direction. The contact plug may extend in the vertical direction through the second gate structure. The contact plug may be insulated from the second gate structure, and may contact an upper surface of the first source/drain layer.

According to some implementations of the present disclosure, there is provided a semiconductor device. The semiconductor device may include a first transistor, a second transistor, insulation patterns, and first to third contact plugs. The first transistor may include first channels, a first gate structure and a first source/drain layer. The first channels may be disposed on a substrate, and may be spaced apart from each other in a vertical direction substantially perpendicular to an upper surface of the substrate. The first gate structure may extend on the substrate in a first direction substantially parallel to the upper surface of the substrate, and may cover upper and lower surfaces and opposite sidewalls in the first direction of the first channels. The first source/drain layer may be disposed at opposite sides of the first gate structure in a second direction substantially parallel to the upper surface of the substrate and substantially perpendicular to the first direction. The second transistor may include second channels, a second gate structure and a second source/drain layer. The second channels may be disposed on the first channels, and may be spaced apart from each other in the vertical direction. The second gate structure may extend on the substrate in the second direction, and may cover upper and lower surfaces and opposite sidewalls in the second direction of the second channels. The second source/drain layer may be disposed at opposite sides of the second gate structure in the first direction. The insulation patterns may be disposed between and spaced apart from the first and second channels, and may be aligned with the first and second channels in the vertical direction and being spaced apart from each other. The first contact plug may extend in the vertical direction and contact an upper surface of the first source/drain layer. The second contact plug may contact an upper surface of the second source/drain layer. The third contact plug may contact an upper surface of the second gate structure.

The semiconductor device in accordance with the foregoing and other implementations may include the first and second transistors stacked in the vertical direction and disposed in orthogonal directions, and the first and second source/drain layers included in the first and second transistors, respectively, may not overlap each other in the vertical direction. Thus, the contact plug connected to an upper wiring and transferring electrical signals to the first source/drain layer may extend in the vertical direction to contact the first source/drain layer without penetrating through the second source/drain layer. Accordingly, an additional conductive structure for detouring the second source/drain layer may not be formed, and the manufacturing process may be simplified and the integration degree of the semiconductor device may be enhanced.

### BRIEF DESCRIPTION OF THE DRAWINGS

FIGS. 1 to 8 are perspective views and cross-sectional views illustrating an example of a semiconductor device in.

FIGS. 9 to 41 are perspective views and cross-sectional views illustrating an example of a method of manufacturing a semiconductor device.

FIG. 42 is a cross-sectional view illustrating an example of a semiconductor device.

### DETAILED DESCRIPTION

It will be understood that, although the terms “first,” “second,” and/or “third” may be used herein to describe various elements, these terms are only used to distinguish one element from another element.

In the following description, two directions among horizontal directions that are substantially parallel to an upper surface of a substrate, which may intersect each other, may be referred to as first and second directions D1 and D2, respectively, and a vertical direction that is substantially perpendicular to the upper surface of the substrate may be referred to as a third direction D3. In some implementations, the first and second directions D1 and D2 are substantially perpendicular to each other.

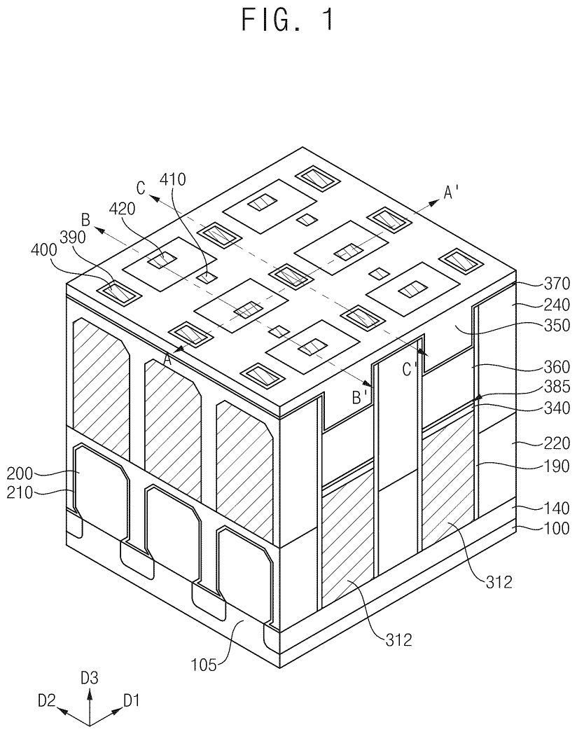

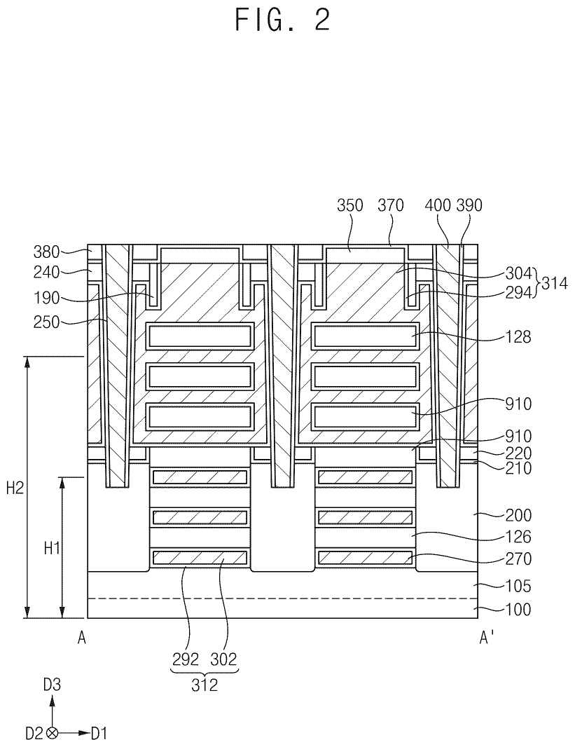

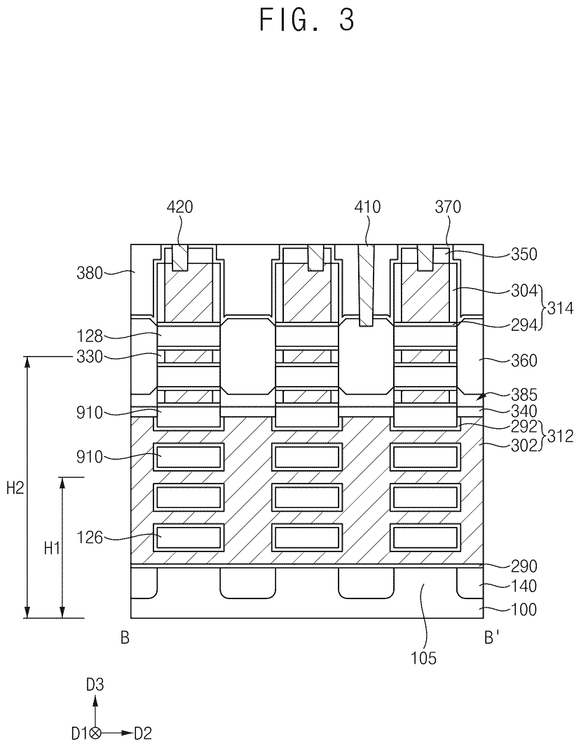

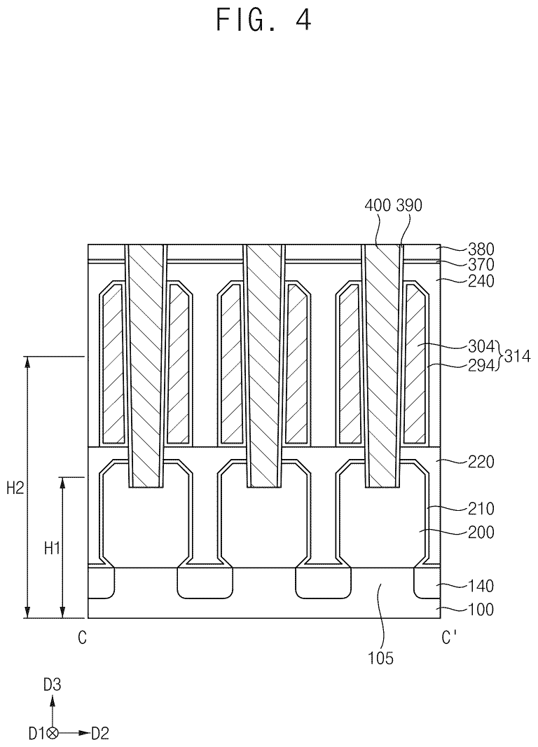

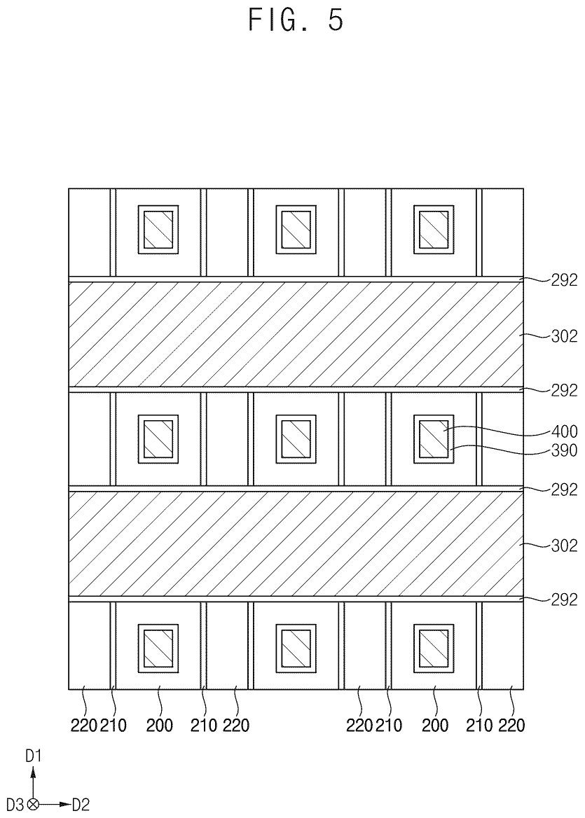

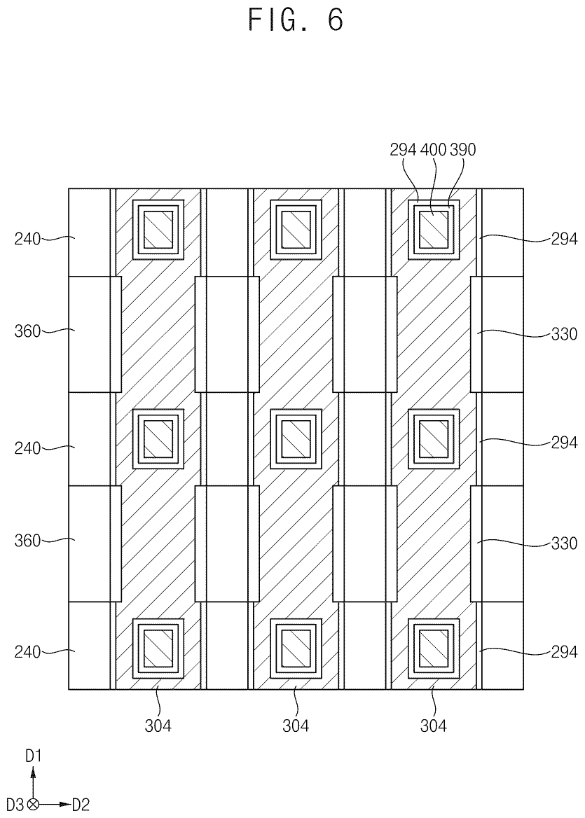

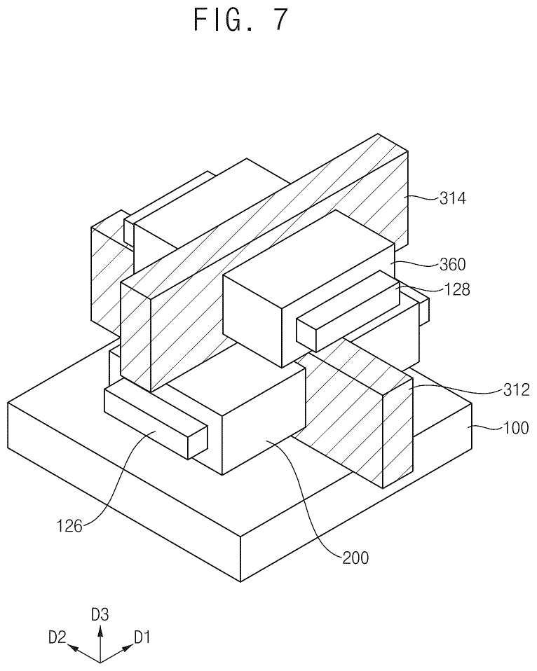

FIGS. 1 to 8 are perspective views and cross-sectional views illustrating an example of a semiconductor device. Particularly, FIGS. 1 and 7 are the perspective views, FIGS. 2 to 6 are the cross-sectional views. FIG. 2 is a vertical cross-sectional view taken along line A-A′ of FIG. 1, FIG. 3 is a vertical cross-sectional view taken along line B-B′ of FIG. 1, and FIG. 4 is a vertical cross-sectional view taken along line C-C′ of FIG. 1. FIG. 5 is a horizontal cross-sectional view at a first height H1 shown in FIGS. 2 to 4, and FIG. 6 is a horizontal cross-sectional view at a second height H2 shown in FIGS. 2 to 4.

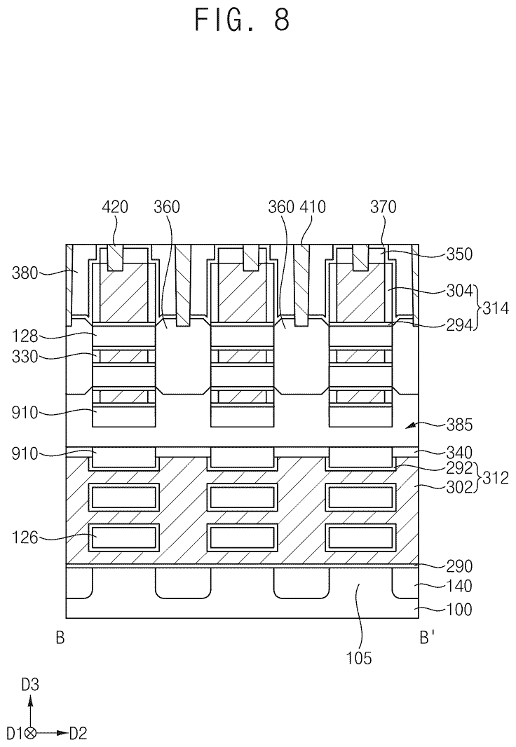

FIG. 7 is a schematic view of main elements of first and second transistors included in the semiconductor device, and FIG. 8 is a cross-sectional view corresponding to FIG. 3 and is a drawing illustrating some regions of the semiconductor device.

Referring to FIGS. 1 to 8, the semiconductor device may include an active pattern 105, an isolation pattern 140, first and second semiconductor patterns 126 and 128, first and second gate structures 312 and 314, first and second source/drain layers 200 and 360, a gate spacer 190, an inner spacer 330, first to third contact plugs 400, 410 and 420, first to third capping patterns 210, 340 and 350, an etch stop layer 370, first to third insulating interlayer patterns 220, 240 and 380, and first and second insulation patterns 910 and 390 on a substrate 100.

The substrate 100 may include a semiconductor material, e.g., silicon, germanium, silicon-germanium, etc., or III-V semiconductor compounds, e.g., GaP, GaAs, GaSb, etc. In some implementations, the substrate 100 includes a silicon-on-insulator (SOI) substrate or a germanium-on-insulator (GOI) substrate.

The active pattern 105 may protrude beyond the substrate 100, and a sidewall of the active pattern 105 may be covered by the isolation pattern 140.

In some implementations, the active pattern 105 extends in the first direction D1, and a plurality of active patterns 105 may be spaced apart from each other in the second direction D2.

In some implementations, the isolation pattern 140 may extend in the first direction D1 between neighboring two active patterns 105 in the second direction D2, and a plurality of isolation patterns 140 may be spaced apart from each other in the second direction D2.

The active pattern 105 may include substantially the same material as the substrate 100, and the isolation pattern 140 may include an oxide, e.g., silicon oxide.

The first semiconductor patterns 126 may be disposed at a plurality of levels, respectively, spaced apart from each other in the third direction D3 on an upper surface of the active pattern 105, and the second semiconductor patterns 128 may be disposed at a plurality of levels, respectively, spaced apart from each other in the third direction D3 over the first semiconductor patterns 126. The first insulation patterns 910 may be disposed at two levels, respectively, between an uppermost one of the first semiconductor patterns 126 and a lowermost one of the second semiconductor patterns 128.

In some implementations, the first and second semiconductor patterns 126 and 128 and the first insulation pattern 910 have substantially the same shape and size, and the first and second semiconductor patterns 126 and 128 and the first insulation pattern 910 may be aligned with and overlap each other in the third direction D3.

FIGS. 2 and 3 show that the first semiconductor patterns 126 are disposed at three levels, respectively, and the second semiconductor patterns 128 are disposed at two levels, respectively, however, the arrangement is not limited thereto, and the first and second semiconductor patterns 126 and 128 may be disposed at more or less than three or two levels, respectively.

In some implementations, each of the first and second semiconductor patterns 126 and 128 and the first insulation pattern 910 has a bar shape, or rectangular shape, having a first length in the first direction D1 greater than a second length in the second direction D2, which is shown in FIGS. 2 and 3. However, the shape is not limited thereto, and for example, each of the first and second semiconductor patterns 126 and 128 and the first insulation pattern 910 may have a bar shape having a first length in the first direction D1 less than a second length in the second direction D2, or a plate shape having the same length in the first and second directions D1 and D2.

FIG. 2 shows that two first semiconductor patterns 126 are spaced apart from each other in the first direction D1, two second semiconductor patterns 128 are spaced apart from each other in the first direction D1, and two first insulation patterns 910 are spaced apart from each other in the first direction D1 at each level on the active pattern 105 extending in the first direction D1, however, the number and arrangement of these patterns is not limited thereto.

In some implementations, each of the first and second semiconductor patterns 126 and 128 may serve as a channel in a transistor including the first semiconductor pattern 126 or the second semiconductor pattern 128, and thus may also be referred to as first and second channels, respectively.

Each of the first and second semiconductor patterns 126 and 128 may include, e.g., single crystalline silicon or polysilicon, and the first insulation pattern 910 may include an insulating material, e.g., silicon oxycarbonitride (SiOCN).

The first gate structure 312 may extend in the second direction D2 on the active pattern 105 and the isolation pattern 140, and may include a first gate electrode 302 and a first gate insulation pattern 292. The first gate insulation pattern 292 may include a first interface pattern and a first high-k dielectric pattern sequentially stacked on upper surfaces of the active pattern 105 and the isolation pattern 140 and surfaces of the first semiconductor pattern 126 and the first insulation pattern 910.

Additionally, the second gate structure 314 may extend in the first direction D1 on the first insulating interlayer pattern 220, the first capping pattern 210 and the first insulation pattern 910, and may include a second gate electrode 304 and a second gate insulation pattern 294. The second gate insulation pattern 294 may include a second interface pattern and a second high-k dielectric pattern sequentially stacked on upper surfaces of the first insulating interlayer pattern 220, the first capping pattern 210 and the first insulation pattern 910, surfaces of the second semiconductor pattern 128 and the first insulation pattern 910, a sidewall of the second insulation pattern 390 on a sidewall of the first contact plug 400, and a sidewall and a lower surface of the gate spacer 190.

In some implementations, as shown in FIG. 3, the first gate structure 312 covers upper and lower surfaces and opposite sidewalls in the second direction D2 of each of the first semiconductor patterns 126, upper and lower surfaces and opposite sidewalls in the second direction D2 of a lower one of the first insulation patterns 910, and a lower surface of a lower portion and opposite sidewalls in the second direction D2 of an upper one of the first insulation patterns 910. Thus, an upper surface of the first gate structure 312 may be lower than or substantially coplanar with an upper surface of the upper one of the first insulation patterns 910, and may be higher than or substantially coplanar with a lower surface of the upper one of the first insulation patterns 910.

In some implementations, as shown in FIG. 8, the first gate structure 312 covers the upper and lower surfaces and the opposite sidewalls in the second direction D2 of each of the first semiconductor patterns 126, and a lower surface of a lower portion and the opposite sidewalls in the second direction D2 of the lower one of the first insulation patterns 910. Thus, the upper surface of the first gate structure 312 may be lower than or substantially coplanar with an upper surface of the lower one of the first insulation patterns 910, and may be higher than or substantially coplanar with a lower surface of the lower one of the first insulation patterns 910. The first gate structure 312 and the second gate structure 314 may share portions thereof. For example, a portion of the first gate structure 312 between the lower and upper ones of the first insulation patterns 910 may be shared with the second gate structure 314.

In some implementations, the upper surface of the first gate structure 312 is lower than or substantially coplanar with the upper surface of the upper one of the first insulation patterns 910 and higher than or substantially coplanar with the lower surface of the upper one of the first insulation patterns 910, as shown in FIG. 3, in a first region of the semiconductor device, while the upper surface of the first gate structure 312 is lower than or substantially coplanar with the upper surface of the lower one of the first insulation patterns 910 and higher than or substantially coplanar with the lower surface of the lower one of the first insulation patterns 910, as shown in FIG. 8, in a second region of the semiconductor device. In this case, the first gate structure 312 and the second gate structure 314 may not share any portion, and may be spaced apart from each other.

In some implementations, the second capping pattern 340 is disposed on an upper surface of a portion of the first gate structure 312 not overlapped by the lower one of the first insulation patterns 910 in the third direction D3. In some implementations, an upper surface of the second capping pattern 340 is substantially coplanar with the upper surface of the lower one of the first insulation patterns 910, however, the relative arrangement is not limited thereto. The second capping pattern 340 may include an insulating nitride, e.g., silicon nitride.

In some implementations, the second gate structure 314 covers lower and upper surfaces and opposite sidewalls in the first direction D1 of each of the second semiconductor patterns 128. In some implementations, the second gate structure 314 contacts the upper surface of the upper one of the first insulation patterns 910, an upper surface of the first insulating interlayer pattern 220 and an uppermost surface of the first capping pattern 210.

In some implementations, an uppermost surface of a portion of the second gate structure 314 on an uppermost one of the second semiconductor patterns 128 (hereinafter, referred to as an upper portion of the second gate structure 314) is higher than an uppermost surface of a portion of the second gate structure 314 not overlapping the second semiconductor patterns 128 in the third direction D3 (hereinafter, referred to as a vertical extension portion of the second gate structure 314).

The gate spacer 190 may be disposed on each of opposite sidewalls in the first direction D1 of the upper portion of the second gate structure 314. In some implementations, the gate spacer 190 includes substantially the same material as the first insulation pattern 910. For example, the gate spacer 190 may include an insulating material such as silicon oxycarbonitride (SiOCN).

In some implementations, the gate spacer 190 is not disposed on each of opposite lower sidewalls in the first direction D1 of the upper portion of the second gate structure 314, and the upper portion of the second gate structure 314 may contact the vertical extension portion of the second gate structure 314.

For example, a portion of the second gate structure 314 overlapping the second semiconductor patterns 128 in the third direction D3 may contact the vertical extension portions on opposite sides in the first direction D1, and thus the portion and the vertical extension portions may be electrically connected to each other.

The third capping pattern 350 may be disposed on an upper surface of the upper portion of the second gate structure 314, for example, an upper surface of the second gate electrode 304 included in the upper portion of the second gate structure 314. In some implementations, the third capping pattern 350 includes substantially the same material as the second capping pattern 340. For example, the third capping pattern 350 may include an insulating nitride, e.g., silicon nitride.

In some implementations, the inner spacer 330 is disposed on each of opposite sidewalls in the second direction D2 of a portion of the second gate electrode 304 between neighboring ones of the second semiconductor patterns 128 in the third direction D3. For example, a sidewall of the inner spacer 330 that does not contact the second gate electrode 304 may be aligned in the third direction D3 with sidewalls of the second semiconductor patterns 128 over and under the inner spacer 330. The inner spacer 330 may include an insulating nitride, e.g., silicon nitride.

Each of the first and second interface patterns may include an oxide, e.g., silicon oxide, and each of the first and second high-k dielectric patterns may include a metal oxide, e.g., hafnium oxide, zirconium oxide, etc. Each of the first and second gate electrodes 302 and 304 may include a metal nitride, a metal alloy, a metal carbide, a metal oxynitride, a metal carbonitrde, a metal oxycarbonitride, e.g., titanium nitride, titanium aluminum nitride, tantalum nitride, tantalum aluminum nitride, titanium aluminum, titanium aluminum carbide, titanium aluminum oxynitride, titanium aluminum carbonitrde, titanium aluminum oxycarbonitride, etc., or a low-resistance metal, e.g., tungsten, aluminum, copper, tantalum, etc.

The first source/drain layer 200 may be disposed on a portion of the active pattern 105 adjacent to the first gate structure 312, and may contact sidewalls in the first direction D1 of the first semiconductor patterns 126. The first source/drain layer 200 may include a pair of first source/drain layers spaced apart from one another in the first direction D1.

In some implementations, an upper surface of the first source/drain layer 200 is lower than or substantially coplanar with the upper surface of the lower one of the first insulation patterns 910, and is higher than or substantially coplanar with the lower surface of the lower one of the first insulation patterns 910.

In some implementations, the first source/drain layer 200 overlaps a portion of the second gate structure 314 in the third direction D3.

In some implementations, the first source/drain layer 200 includes silicon-germanium doped with p-type impurities, and thus may serve as a source/drain of a PMOS transistor.

The upper surface and a sidewall in the second direction D2 of the first source/drain layer 200 may be covered by the first capping pattern 210, and the first capping pattern 210 may also cover an upper surface of the isolation pattern 140 and a sidewall in the first direction D1 of an upper portion of the lower one of the first insulation patterns 910. The first capping pattern 210 may include an insulating nitride, e.g., silicon nitride.

The first insulating interlayer pattern 220 may be disposed on the first capping pattern 210, and a sidewall and a lower surface of the first insulating interlayer pattern 220 may be covered by the first capping pattern 210. The first insulating interlayer pattern 220 may be disposed in a space between the first source/drain layers 200 neighboring in the second direction D2 and a space over the first source/drain layers 200. In some implementations, an upper surface of the first insulating interlayer pattern 220 is lower than or substantially coplanar with the upper surface of the lower one of the first insulation patterns 910. The first insulating interlayer pattern 220 may include an oxide, e.g., silicon oxide.

The second source/drain layer 360 may be adjacent to the second gate structure 314, and may contact sidewalls in the second direction D2 of the second semiconductor patterns 128. In some implementations, a lower surface of the second source/drain layer 360 is lower than or substantially coplanar with a lower surface of a lowermost one of the second semiconductor patterns 128, and may be higher than an upper surface of the second capping pattern 340.

In some implementations, an air gap 385 is disposed between the second capping pattern 340 and the second source/drain layer 360, which is shown in FIG. 3. In some implementations, the etch stop layer 370 and/or the third insulating interlayer pattern 380 is disposed between the second capping pattern 340 and the second source/drain layer 360. For example, the air gap 385 may not be present.

In some implementations, the second source/drain layer 360 overlaps a portion of the first gate structure 312 in the third direction D3, and may not overlap the first source/drain layer 200.

In some implementations, the second source/drain layer 360 may include crystalline silicon doped with n-type impurities or crystalline silicon carbide doped with n-type impurities, and thus may serve as a source/drain of an NMOS transistor.

The second insulating interlayer pattern 240 may be disposed on the first insulating interlayer pattern 220, and may cover the second gate structure 314. The second insulating interlayer pattern 240 may cover upper surfaces of other portions of the second gate structure 314 except for the upper portion, and may cover an upper sidewall of the gate spacer 190 on each of opposite upper sidewalls in the first direction D1 of the upper portion of the second gate structure 314. In some implementations, an upper surface of the second insulating interlayer pattern 240 is substantially coplanar with an upper surface of the upper portion of the second gate structure 314.

The etch stop layer 370 may be disposed on the upper surface of the second source/drain layer 360, a sidewall in the second direction D2 of the upper portion of the second gate structure 314, a sidewall and an upper surface of the third capping pattern 350, and the upper surface of the second insulating interlayer pattern 240. The third insulating interlayer pattern 380 may be disposed on the etch stop layer 370, and a lower surface and a sidewall of the third insulating interlayer pattern 380 may be covered by the etch stop layer 370.

In some implementations, an upper surface of the third insulating interlayer 380 is substantially coplanar with an upper surface of a portion of the etch stop layer 370 on the upper surface of the third capping pattern 350.

The etch stop layer 370 may include an insulating nitride, e.g., silicon nitride, and the third insulating interlayer pattern 380 may include an oxide, e.g., silicon oxide.

The first contact plug 400 may extend through the third insulating interlayer pattern 380, the etch stop layer 370, the second insulating interlayer pattern 240, the second gate structure 314, the first insulating interlayer pattern 220 and the first capping pattern 210 to contact the upper surface of the first source/drain layer 200, and the second insulation pattern 390 may be disposed on a sidewall of the first contact plug 400. In some cases, the second insulation pattern 390 may also be referred to as a plug insulation pattern 390.

In some implementations, an outer sidewall of the second insulation pattern 390 on a sidewall of a portion of the first contact plug 400 extending through the second gate structure 314 may be covered by the second gate insulation pattern 294 included in the vertical extension portion of the second gate structure 314, and thus the second gate electrode 304 included in the vertical extension portion of the second gate structure 314 may not contact the outer sidewall of the second insulation pattern 390. The second insulation pattern 390 may include an oxide, e.g., silicon oxide.

The second contact plug 410 may extend through the third insulating interlayer pattern 380 and the etch stop layer 370 to contact the upper surface of the second source/drain layer 360. The third contact plug 420 may extend through the etch stop layer 370 and the third capping pattern 350 to contact an upper surface of the second gate electrode 304 of the second gate structure 314, more particularly, an upper surface of a portion of the second gate electrode 304 included in the upper portion of the second gate structure 314.

Each of the first to third contact plugs 400, 410 and 420 may include, e.g., a metal, a metal nitride, a metal silicide, etc.

A fourth contact plug may contact a lower surface of the first gate electrode 302 of the first gate structure 312.

Each of the first to third contact plugs 400, 410 and 420 may be electrically connected to upper wirings over, e.g., the second gate structure 314 and the second source/drain layer 360, and the fourth contact plug may be electrically connected to a lower wiring under, e.g., the first gate structure 312 and the first source/drain layer 200.

In the semiconductor device, the first gate structure 312 extending in the second direction D2, the first source/drain layers 200 at respective opposite sides in the first direction D1 of the first gate structure 312, and the first channel 126 extending through the first gate structure 312 may form a first transistor. A plurality of first channels 126 may be spaced apart from each other in the third direction D3 in the first gate structure 312, and thus the first transistor may be a multi-bridge channel field effect transistor (MBCFET).

The second gate structure 314 extending in the first direction D1, the second source/drain layers 360 at respective opposite sides in the second direction D2 of the second gate structure 314, and the second channel 128 extending through the second gate structure 314 may form a second transistor. A plurality of second channels 128 may be spaced apart from each other in the third direction D3 in the second gate structure 314, and thus the second transistor may also be an MBCFET.

In some implementations, each of the first source/drain layers 200 includes silicon-germanium doped with p-type impurities, and thus the first transistor may be a p-type transistor. Each of the second source/drain layers 360 may include silicon or silicon carbide doped with n-type impurities, and thus the second transistor may be an n-type transistor.

Accordingly, the semiconductor device may include the p-type transistor and the n-type transistor sequentially stacked in the third direction D3 on the substrate 100, and the first gate structure 312 of the p-type transistor and the second gate structure 314 of the n-type transistor may extend in a different directions, e.g., in the second direction D2 and the first direction D1, respectively, which may be substantially perpendicular to each other.

The first and second source/drain layers 200 and 360 at opposite sides in the first and second gate structures 312 and 314, respectively, may not overlap each other in the third direction D3. For example, the first and second source/drain layers 200 and 360 may be spaced apart from one another in at least one of the first or second directions D1 and/or D2. For example, the first transistor including the first gate structure 312 and the first source/drain layer 200 and the second transistor including the second gate structure 314 and the second source/drain layers 360 may not disposed in (or extend in or along) the same direction but may be disposed in (or extend in or along) different directions, e.g., orthogonal directions, and the first gate structure 312 and the second gate structure 314 may overlap the second source/drain layer 360 and the first source/drain layer 200, respectively, in the third direction D3.

In some implementations, the semiconductor device includes the n-type transistor and the p-type transistor sequentially stacked in the third direction D3 on the substrate 100.

In some implementations, as shown in FIG. 3, if the upper surface of the first gate structure 312 is higher than the upper surface of the lower one of the first insulation patterns 910, the first and second gate structures 312 and 314 may be electrically connected to each other. In some implementations, if the upper surface of the first gate structure 312 is lower than the upper surface of the lower one of the first insulation patterns 910, the first and second gate structures 312 and 314 may not be electrically connected to each other.

In some implementations, the first and second gate structures 312 and 314 are electrically connected to each other in a first region of the semiconductor device (e.g., with a configuration as shown in FIG. 3), while the first and second gate structures 312 and 314 may not be electrically connected to each other in a second region of the semiconductor device (e.g., with a configuration as shown in FIG. 8).

In some implementations, the first contact plug 400 extends through the second gate structure 314 to contact the first source/drain layer 200, the second contact plug 410 may contact the second source/drain layer 360, and the third contact plug 420 may contact the second gate electrode 304 of the second gate structure 314.

If first and second gate structures included in a p-type transistor and an n-type transistor, respectively, have the same extension direction, first and second source/drain layers at opposite sides of the first and second gate structures, respectively, may overlap each other in the vertical direction. When a first contact plug for transferring electrical signals to the first source/drain layer, which is disposed under the second source/drain layer, is disposed over the second source/drain layer, the first contact plug extends through the second source/drain layer, and thus the electrical characteristics of the second source/drain layer may be deteriorated.

In order to detour the second source/drain layer, an additional contact plug that contacts the first source/drain layer and has a long extension length in the horizontal direction may be formed, and a via that contacts the additional contact plug may be formed to be connected to an upper wiring. In this case, processes for forming the additional contact plug and the via are needed, and the integration degree of the semiconductor device may decrease.

However, in some implementations according to the present disclosure, the first and second source/drain layers 200 and 360 do not overlap each other in the third direction D3, and thus the first contact plug 400 for transferring electrical signals from an upper wiring to the first source/drain layer 200 may extend in the third direction D3 to contact the upper surface of the first source/drain layer 200 without penetrating through the second source/drain layer 360. Accordingly, a conductive structure for detouring the second source/drain layer 360, in addition to the first contact plug 400, is not required so that the processes may be simplified and the integration degree of the semiconductor device may increase.

The fourth contact plug may contact the lower surface of the first gate electrode 302 of the first gate structure 312, which may be disposed under the fourth contact plug, and may be electrically connected to the first gate electrode 302.

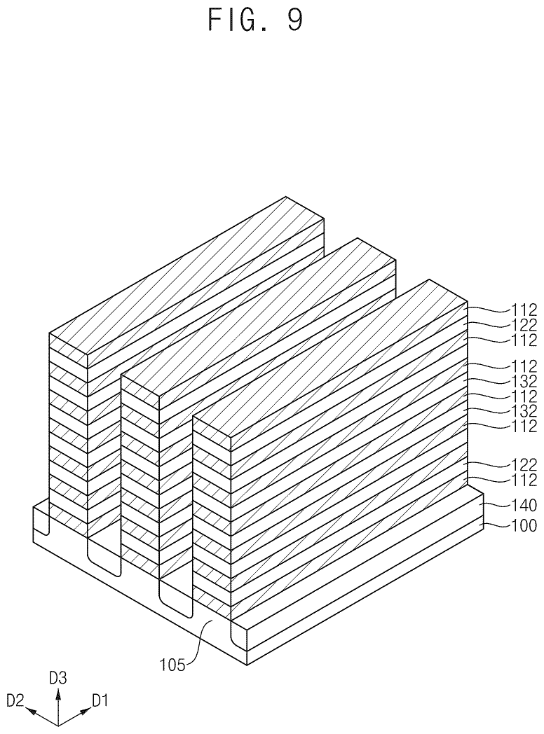

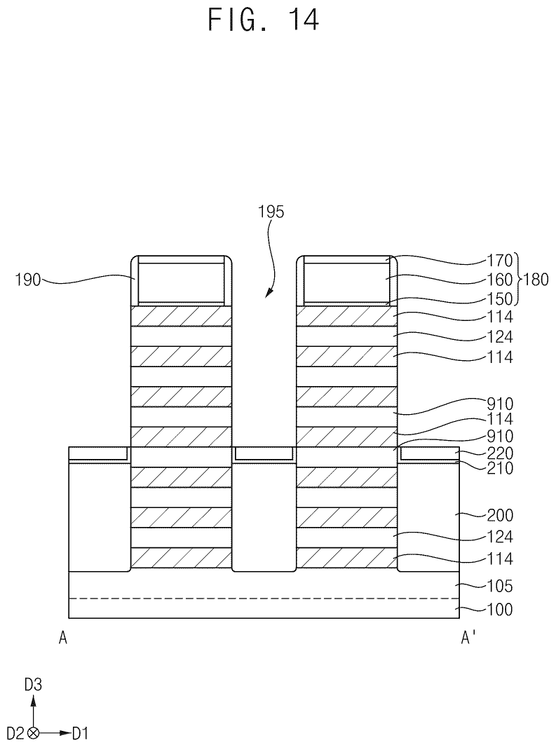

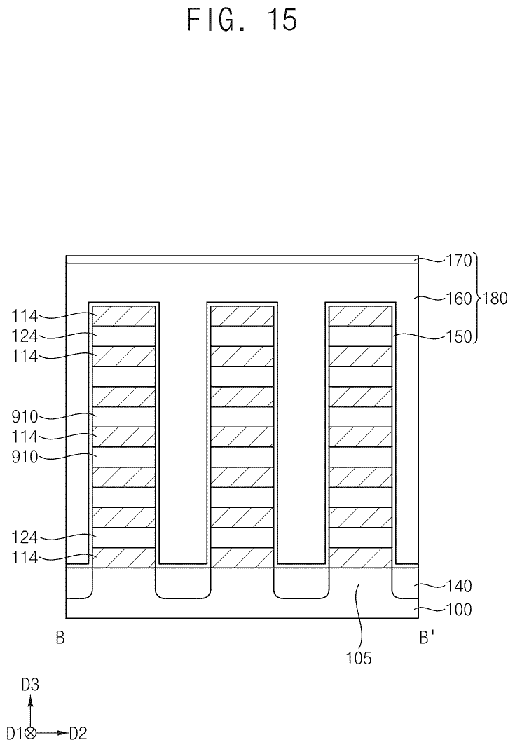

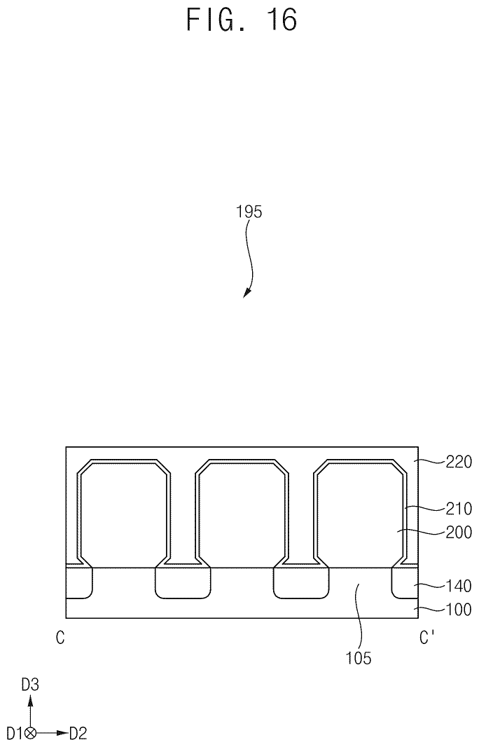

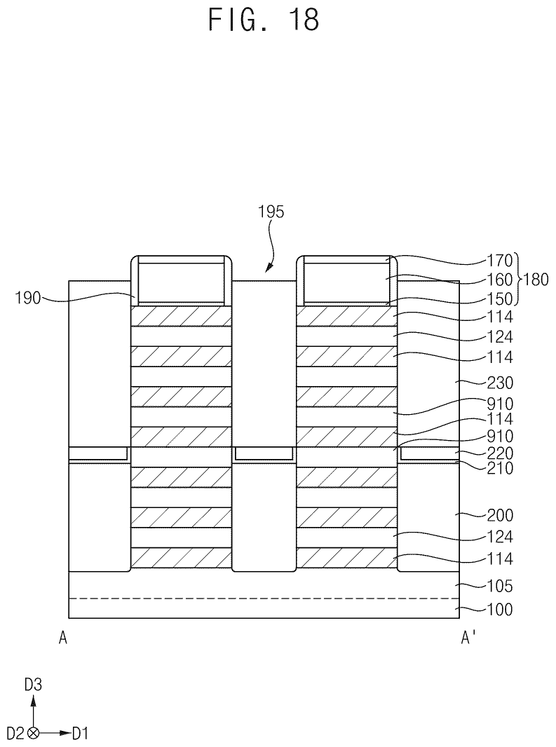

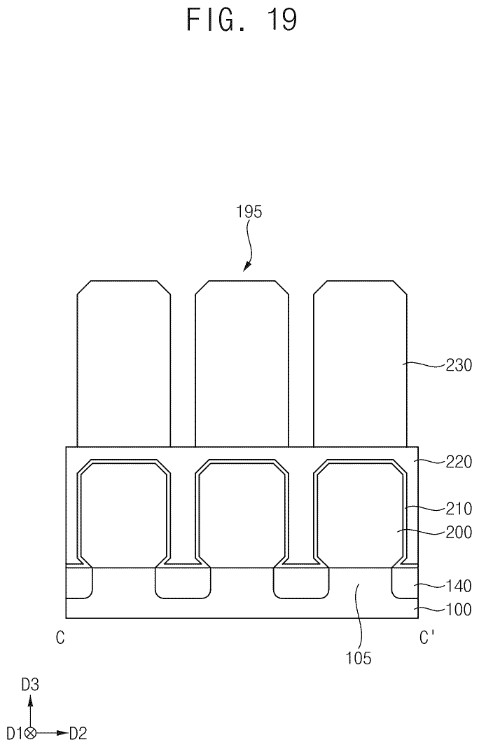

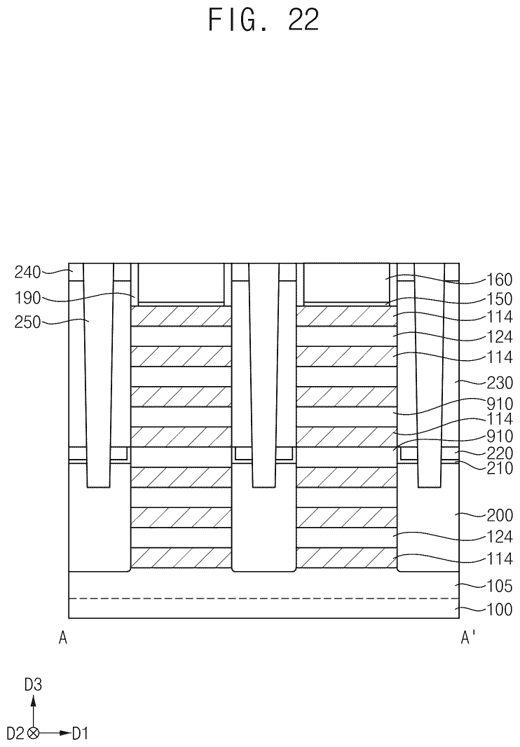

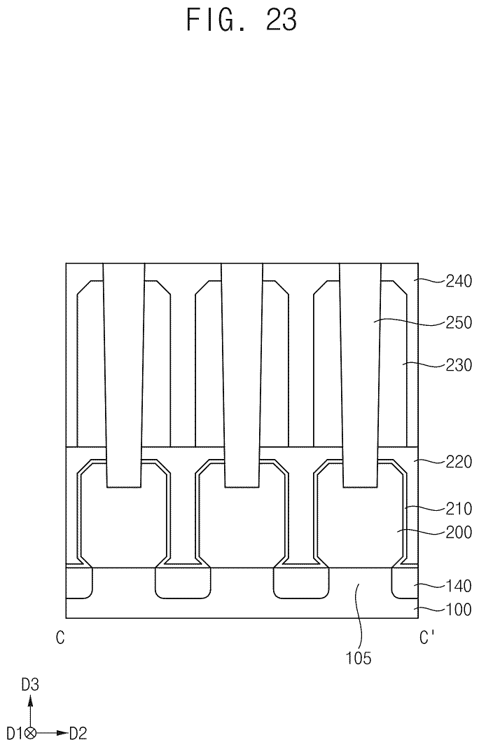

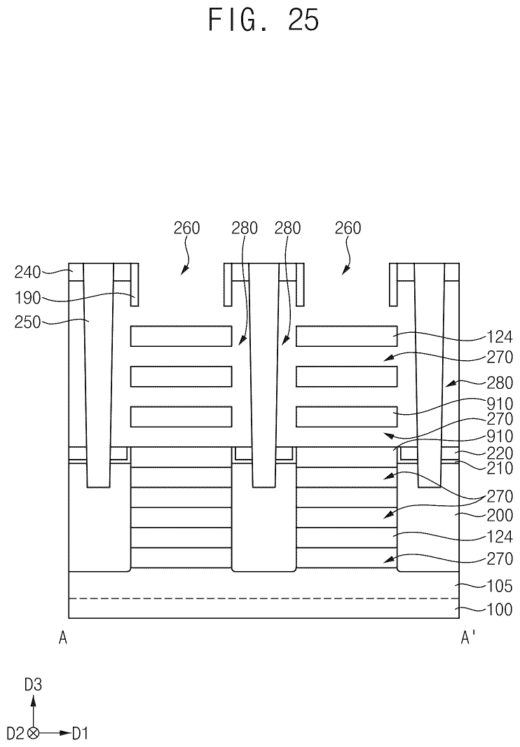

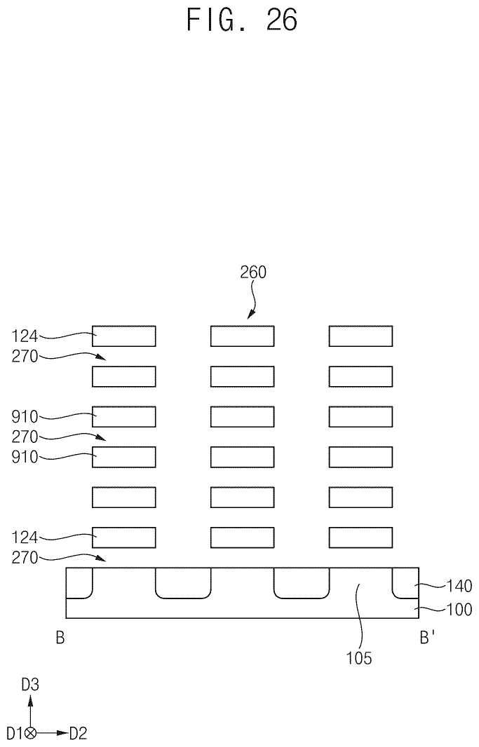

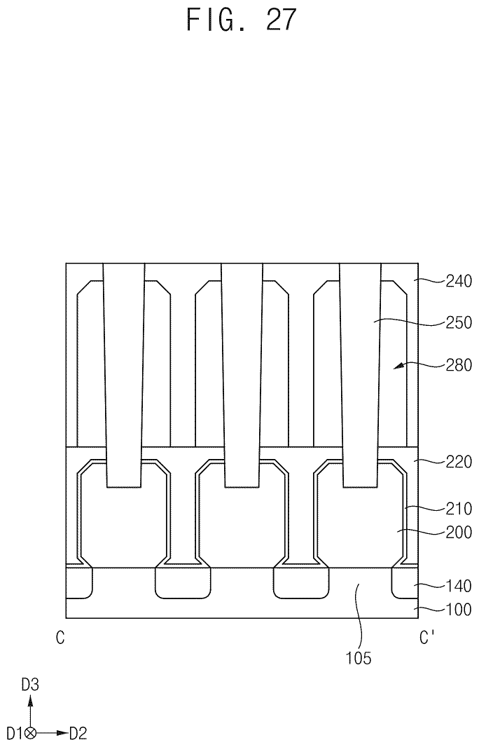

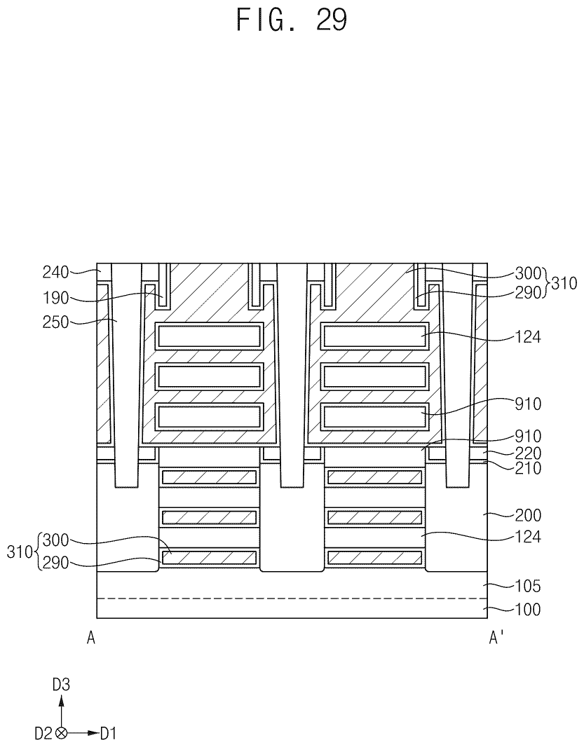

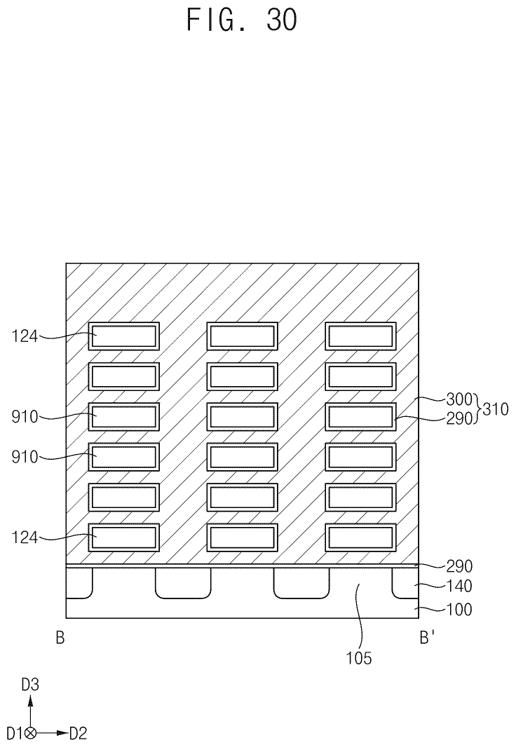

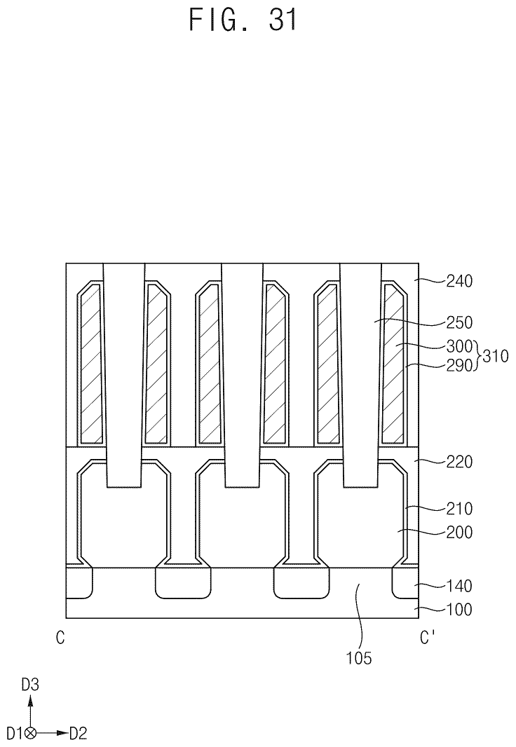

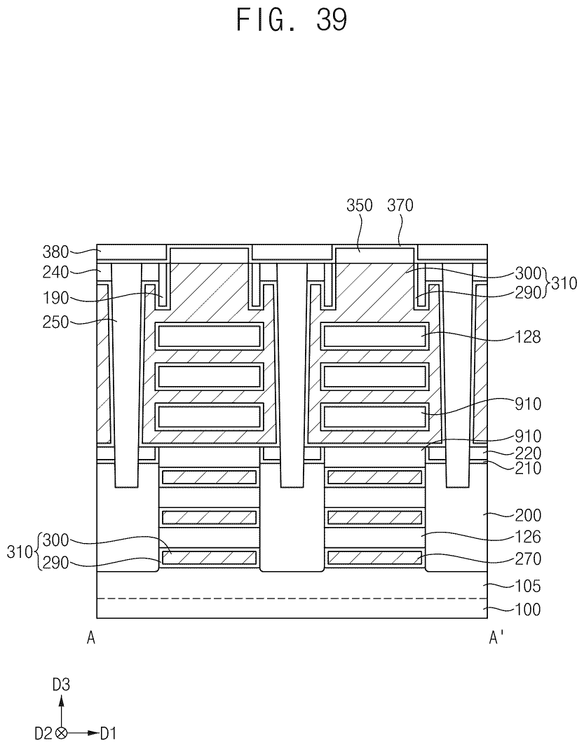

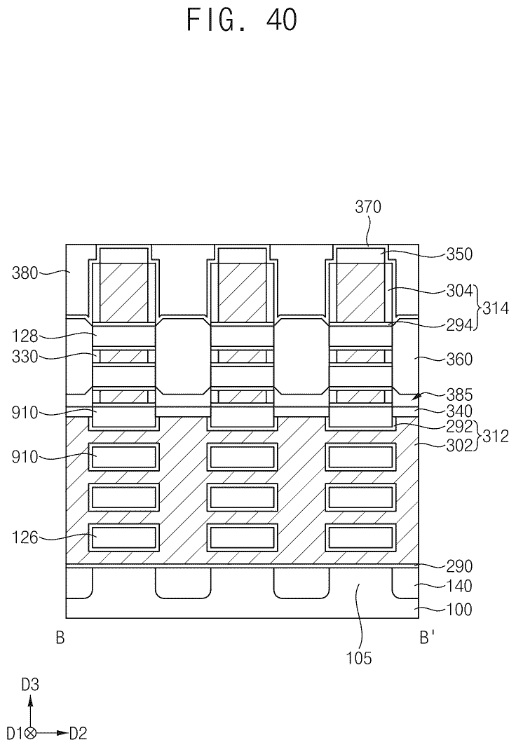

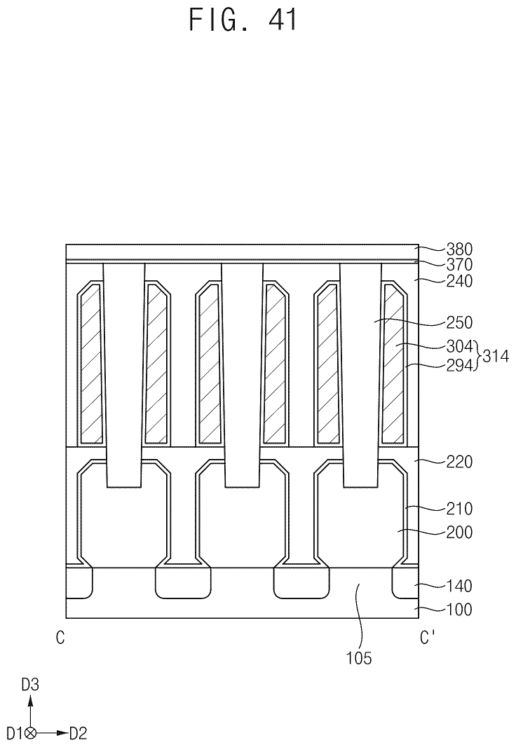

FIGS. 9 to 41 are perspective views and cross-sectional views illustrating a method of manufacturing an example of a semiconductor device. Particularly, FIGS. 9-13, 17, 20-21, 24, 28, 32, 34, 36 and 38 are the perspective views, and FIGS. 14, 18, 22, 25, 29 and 39 are cross-sectional views taken along lines A-A′ of corresponding plan views, respectively, FIGS. 15, 26, 30, 33, 35, 37 and 40 are cross-sectional views taken along lines B-B′ of corresponding plan views, respectively, and FIGS. 16, 19, 23, 27, 31 and 41 are cross-sectional views taken along lines C-C′ of corresponding plan views, respectively.

Referring to FIG. 9, a first sacrificial layer and a semiconductor layer may be alternately and repeatedly stacked on a substrate 100 in the third direction D3, a second sacrificial layer, the first sacrificial layer and the second sacrificial layer may be sequentially stacked on an uppermost one of the first sacrificial layers, and the first sacrificial layer and the semiconductor layer may be alternately and repeatedly stacked on an upper one of the second sacrificial layers to form a stack structure.

In some implementations, the first and second sacrificial layers and the semiconductor layer are formed by a selective epitaxial growth (SEG) process using an upper surface of the substrate 100 as a seed. The semiconductor layer may include, e.g., single crystalline silicon, and each of the first and second sacrificial layers may include a material having an etching selectivity with respect to the substrate 100 and the semiconductor layer, e.g., single crystalline silicon-germanium. In some implementations, a germanium concentration of the second sacrificial layer is different from a germanium concentration of the first sacrificial layer, and for example, the germanium concentration of the second sacrificial layer may be greater than the germanium concentration of the first sacrificial layer.

In some implementations, the first and second sacrificial layers and the semiconductor layer are formed by a deposition process, e.g., a chemical vapor deposition (CVD) process, an atomic layer deposition (ALD) process, etc. In at least this case, the semiconductor layer may include, e.g., polysilicon, and each of the first and second sacrificial layers may include silicon-germanium. The germanium concentrations of the first and second sacrificial layers may be different from each other.

A first etching mask extending in the first direction D1 may be formed on the stack structure, and the stack structure and an upper portion of the substrate 100 may be etched using the first etching mask.

Thus, an active pattern 105 extending in the first direction D1 may be formed on the substrate 100, and a lower stack line structure including first sacrificial lines 112 and semiconductor lines 122 alternately and repeatedly stacked in the third direction D3, a second sacrificial line 132, the first sacrificial line 112 and the second sacrificial line 132, and an upper stack line structure including the first sacrificial lines 112 and the semiconductor lines 122 alternately and repeatedly stacked in the third direction D3 may be formed on the substrate 100.

The lower stack line structure, the second sacrificial line 132, the first sacrificial line 112, the second sacrificial line 132 and the upper stack line structure may collectively form a stack line structure. In some implementations, the stack line structure extends in the first direction D1 on the substrate 100, and a plurality of stack line structures may be spaced apart from each other in the second direction D2.

FIG. 9 shows that each of the lower and upper stack line structures may include the first sacrificial lines 112 at three levels, respectively, and the semiconductor lines at two levels, respectively, however, their number and arrangement are not limited thereto, and each of the lower and upper stack line structures may include the first sacrificial lines 112 at more than three levels, respectively, and the semiconductor lines at more than two levels, respectively. In some implementations, a lowermost layer and an uppermost layer of each of the lower and upper stack line structures is the first sacrificial lines 112.

An isolation pattern 140 may be formed to cover a sidewall of the active pattern 105.

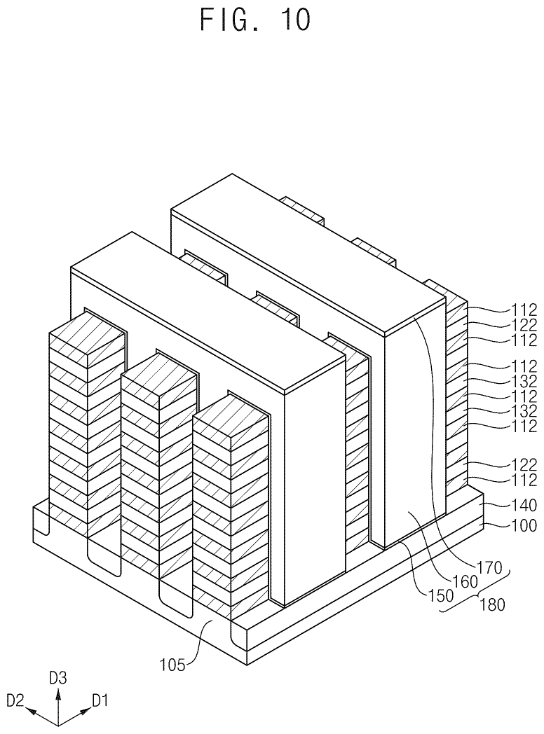

Referring to FIG. 10, a dummy gate insulation layer, a dummy gate electrode layer and a dummy gate mask layer may be sequentially formed on the substrate 100 to cover the stack line structure and the isolation pattern 140, a second etching mask extending in the second direction D2 may be formed on the dummy gate mask layer, and the dummy gate mask layer may be etched using the second etching mask to form a dummy gate mask 170 on the substrate 100.

The dummy gate electrode layer and the dummy gate insulation layer may be etched using the dummy gate mask 170 as an etching mask to form a dummy gate electrode 160 and a dummy insulation pattern 150, respectively.

The dummy gate insulation pattern 150, the dummy gate electrode 160 and the dummy gate mask 170 may collectively form a dummy gate structure 180.

In some implementations, the dummy gate structure 180 extends in the second direction D2 on the stack line structure and the isolation pattern 140, and may cover an upper surface and opposite sidewalls in the second direction D2 of the stack line structure. In some implementations, a plurality of dummy gate structures 180 are spaced apart from each other in the first direction D1.

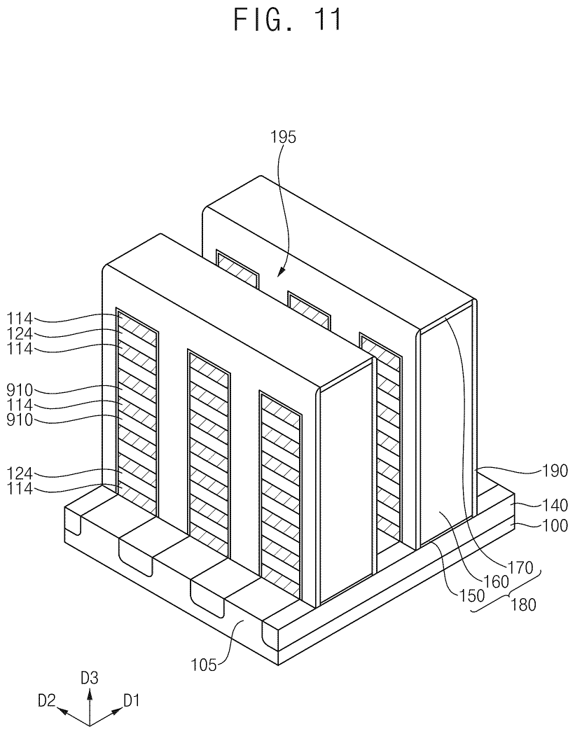

Referring to FIG. 11, the second sacrificial line 132 may be removed by, e.g., a wet etching process to form a first gap, a gate spacer layer may be formed on the substrate 100 having the stack line structure, the isolation pattern 140 and the dummy gate structure 180 thereon to cover the first gap, the gate spacer layer and a portion of the stack line structure not covered by the dummy gate structure 180 may be etched by an etching process to form a gate spacer 190 on each of opposite sidewalls in the first direction D1 of the dummy gate structure 180.

During the etching process, the first sacrificial lines 112 and the semiconductor lines 122 under the dummy gate structure 180 and the gate spacer 190 may be divided into first sacrificial patterns 114 and semiconductor patterns 124, respectively, and a portion of the gate spacer layer in the first gap may be transformed into a first insulation pattern 910.

Thus, the stack line structure extending in the first direction D1 may be divided into first stack structures spaced apart from each other in the first direction D1. Each of the first stack structures may include a first lower stack structure, the first insulation pattern 910, the first sacrificial pattern 114, the first insulation pattern 910 and a first upper stack structure sequentially stacked in the third direction D3.

Hereinafter, the dummy gate structure 180, the gate spacers 190 on opposite sidewalls of the dummy gate structure 180, and the first stack structures spaced apart from each other in the second direction D2 under the dummy gate structure 180 and the gate spacers 190 may be collectively referred to as a second stack structure. In some implementations, the second stack structure may extend in the second direction D2, and a plurality of second stack structures may be spaced apart from each other in the first direction D1.

A first opening 195 extending in the second direction D2 between ones of the second stack structures neighboring in the first direction D1 may be formed to expose upper surfaces of the active pattern 105 and the isolation pattern 140.

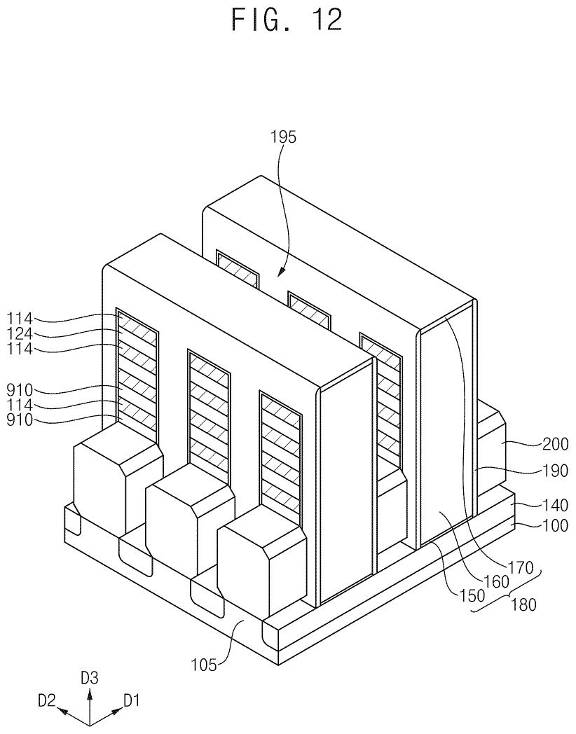

Referring to FIG. 12, a third sacrificial layer may be formed on the active pattern 105 and the isolation pattern 140 to fill a lower portion of the first opening 195, a fourth sacrificial layer may be formed on the third sacrificial layer and the second stack structure, an anisotropic etching process may be performed on the fourth sacrificial layer to remove portions of the fourth sacrificial layer on upper surfaces of the second stack structure and the third sacrificial layer so that the upper surface of the third sacrificial layer may be exposed, and the third sacrificial layer may be removed by, e.g., an ashing process and/or a stripping process so that the upper surfaces of the active pattern 105 and the isolation pattern 140 may be exposed.

In some implementations, the upper surface of the third sacrificial layer is higher than or substantially coplanar with a lower surface of a lower one of the first insulation patterns 910 and lower than or substantially coplanar with an upper surface of the lower one of the first insulation patterns 910.

The third sacrificial layer may include spin-on-hardmask (SOH), amorphous carbon layer (ACL), etc., and the fourth sacrificial layer may include an insulating nitride, e.g., silicon nitride.

A first selectivity epitaxial growth (SEG) process may be performed using the upper surface of the active pattern 105 as a seed to form a first source/drain layer 200 in a lower portion of the first opening 195.

In some implementations, the first SEG process may be performed using a silicon source gas, e.g., dichlorosilane (SiH₂Cl₂) gas, a germanium source gas, e.g., germane (GeH₄) gas, and a p-type impurity source gas, e.g., diborane (B₂H₆) gas, and thus the first source/drain layer 200 may be formed to include a single crystalline silicon-germanium doped with p-type impurities.

In some implementations, an upper surface of the first source/drain layer 200 may be higher than or substantially coplanar with the lower surface of the lower one of the first insulation patterns 910, and lower than or substantially coplanar with the upper surface of the lower one of the first insulation patterns 910.

The fourth sacrificial layer may be removed by, e.g., a wet etching process.

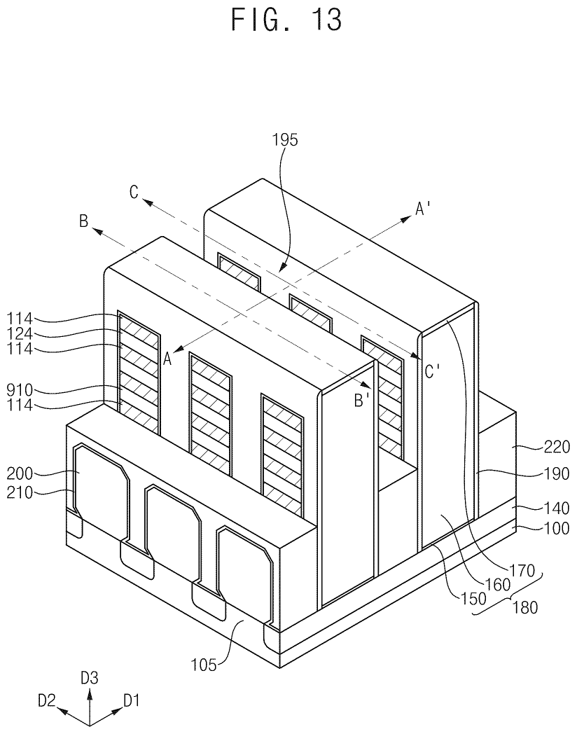

Referring to FIGS. 13 to 16, a first capping layer may be formed on the second stack structure, the first source/drain layer 200 and the isolation pattern 140, a first insulating interlayer may be formed on the first capping layer to fill the first opening 195, and for example, an etch back process may be performed on an upper portion of the first insulating interlayer to form a first insulating interlayer pattern 220 to fill the lower portion of the first opening 195.

During the etch back process, an upper portion of the first capping layer may also be removed, and thus a first capping pattern 210 having an uppermost surface substantially coplanar with an upper surface of the first insulating interlayer pattern 220 may be formed. The first capping pattern 210 may be formed on the upper surface of the isolation pattern 140, the upper surface and opposite sidewalls in the second direction D2 of the first source/drain layer 200, opposite sidewalls in the first direction D1 of the first insulation patterns 910, and opposite sidewalls in the first direction D1 of the first sacrificial pattern 114 between neighboring ones of the first insulation patterns 910.

In some implementations, the upper surface of the first insulating interlayer pattern 220 and the uppermost surface of the first capping pattern 210 is lower than an upper surface of the first sacrificial pattern 114 between the first insulation patterns 910. In some implementations, the upper surface of the first insulating interlayer pattern 220 and the uppermost surface of the first capping pattern 210 is lower than a lower surface of the first sacrificial pattern 114 between the first insulation patterns 910.

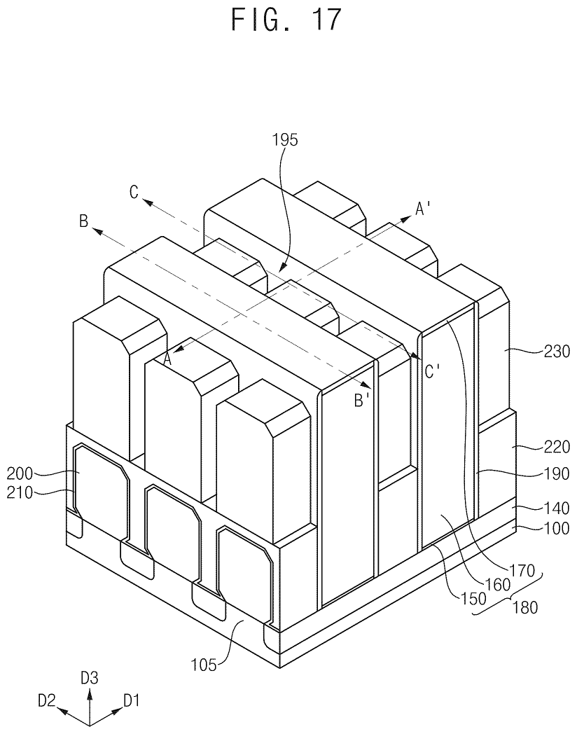

Referring to FIGS. 17 to 19, a second SEG process may be performed using the first sacrificial pattern 114 and the semiconductor pattern 124 included in the first upper stack structure as a seed to form a fifth sacrificial layer 230 in an upper portion of the first opening 195.

In some implementations, the second SEG process may be performed using a silicon source gas, e.g., dichlorosilane (SiH₂Cl₂) gas and a germanium source gas, e.g., germane (GeH₄) gas, and thus a fifth sacrificial layer 230 may be formed to include a single crystalline silicon-germanium. In some implementations, the second SEG process is performed using a p-type impurity source gas, e.g., diborane (B₂H₆) gas together with the silicon source gas and the germanium source gas, and the fifth sacrificial layer 230 may be formed to include a single crystalline silicon-germanium doped with p-type impurities.

In some implementations, a lower surface of the fifth sacrificial layer 230 may contact the upper surface of the first insulating interlayer pattern 220 and the uppermost surface of the first capping pattern 210, and an upper surface of the fifth sacrificial layer 230 may be higher than or substantially coplanar with an upper surface of the first upper stack structure.

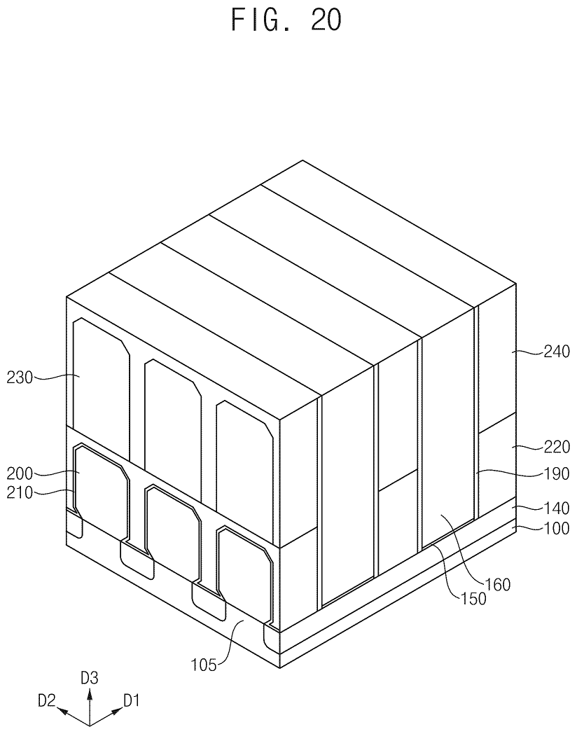

Referring to FIG. 20, a second insulating interlayer may be formed on the fifth sacrificial layer 230, the first insulating interlayer pattern 220, the first capping pattern 210 and the second stack structure to fill a remaining portion of the first opening 195, and a planarization process may be performed on the second insulating interlayer until an upper surface of the dummy gate electrode 160 included in the second stack structure is exposed to form a second insulating interlayer pattern 240.

The planarization process may include, e.g., a chemical mechanical polishing (CMP) process and/or an etch back process. During the planarization process, the dummy gate mask 170 included in the dummy gate structure 180 may be removed, and an upper portion of the gate spacer 190 may also be removed.

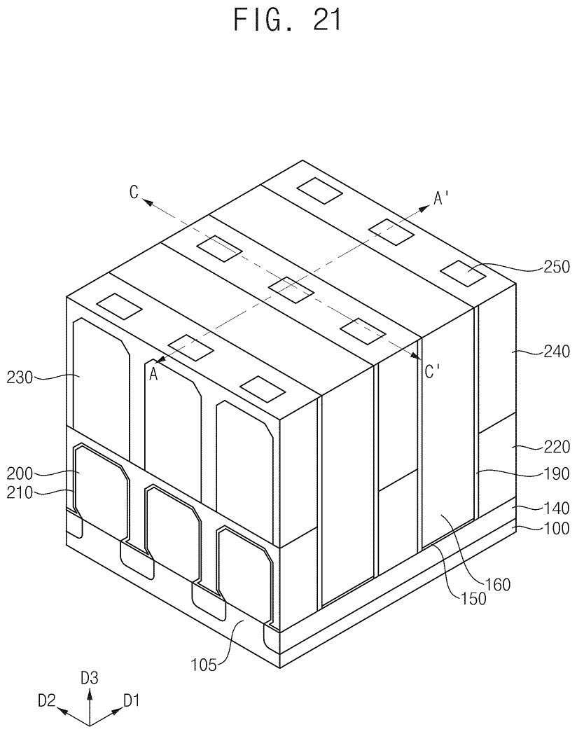

Referring to FIGS. 21 to 23, the second insulating interlayer pattern 240, the fifth sacrificial layer 230, the first insulating interlayer pattern 220 and the first capping pattern 210 may be partially removed to form a second opening exposing the upper surface of the first source/drain layer 200, a sixth sacrificial layer may be formed on the first source/drain layer 200, the second insulating interlayer pattern 240 and the second stack structure to fill the second opening, and a planarization process may be performed on the sixth sacrificial layer until an upper surface of the second stack structure is exposed to form a sixth sacrificial pattern 250 in the second opening.

The sixth sacrificial pattern 250 may include a metal oxide, e.g., aluminum oxide.

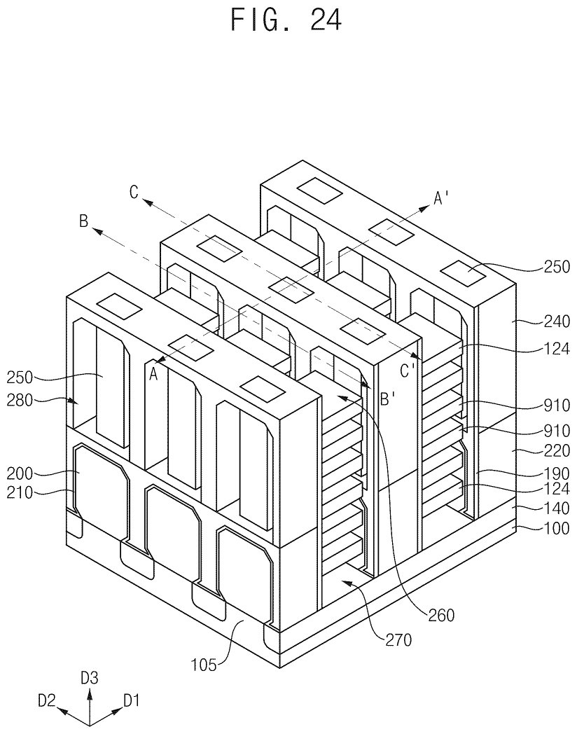

Referring to FIGS. 24 to 27, the dummy gate mask 170, the dummy gate electrode 160 and the dummy gate insulation pattern 150 of the dummy gate structure 180 may be removed to form a third opening 260, and the first sacrificial patterns 114 and the fifth sacrificial layer 230 may be removed to form fourth and fifth openings 270 and 280, respectively.

The dummy gate structure 180, the first sacrificial patterns 114 and the fifth sacrificial layer 230 may be removed by, e.g., a wet etching process and/or a dry etching process.

In some implementations, the fifth opening 280 exposes a portion of a sidewall of the sixth sacrificial pattern 250, and may be connected to upper ones of the fourth openings 270.

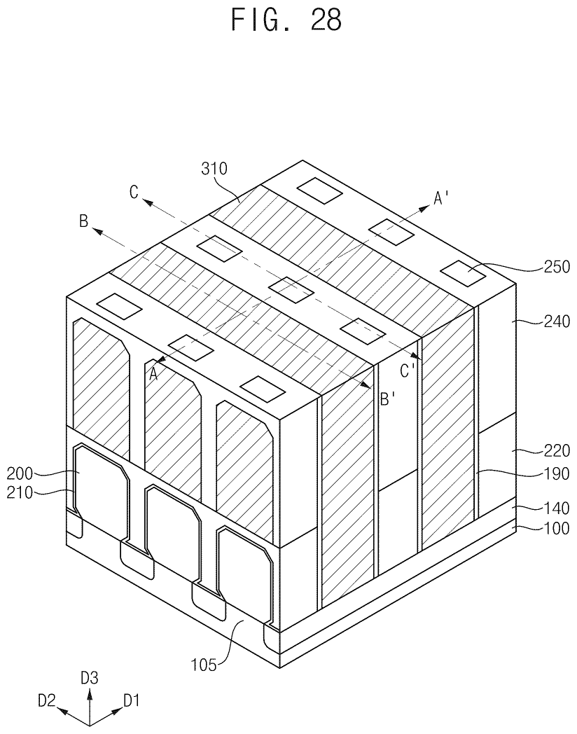

Referring to FIGS. 28 to 31, a gate insulation layer including an interface layer and a high-k dielectric layer may be formed on an inner sidewall and a lower surface of the gate spacer 190, surfaces of the semiconductor patterns 124, the upper surface of the active pattern 105, the upper surface of the isolation pattern 140, the upper surface of the first insulating interlayer pattern 220, the uppermost surface of the first capping pattern 210, a lower surface of the second insulating interlayer pattern 240 and a sidewall of the sixth sacrificial pattern 250, which are exposed by the third to fifth openings 260, 270 and 280, and upper surfaces of the gate spacer 190, the second insulating interlayer pattern 240 and the sixth sacrificial pattern 250, and a gate electrode layer may be formed on the gate insulation layer to fill the third to fifth openings 260, 270 and 280.

The gate electrode layer and the gate insulation layer may be planarized until the upper surface of the second insulating interlayer pattern 240 is exposed, and thus a gate structure 310 including a gate electrode 300 and a gate insulation pattern 290 may be formed in the third to fifth openings 260, 270 and 280.

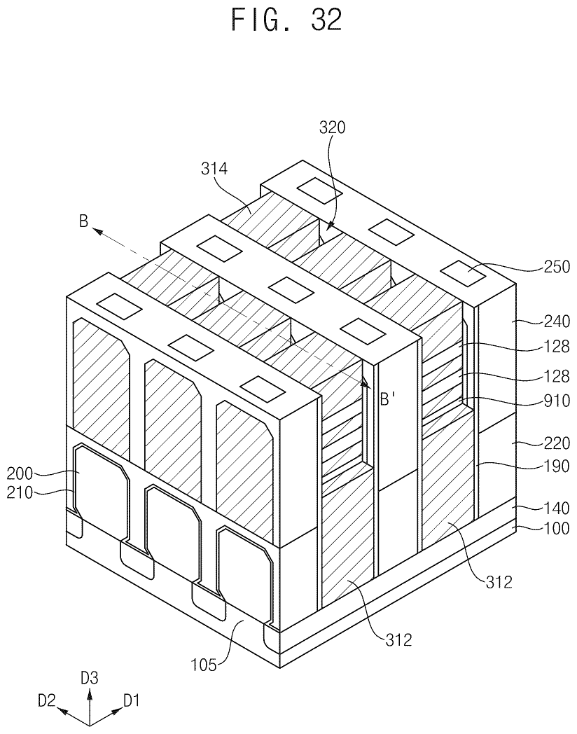

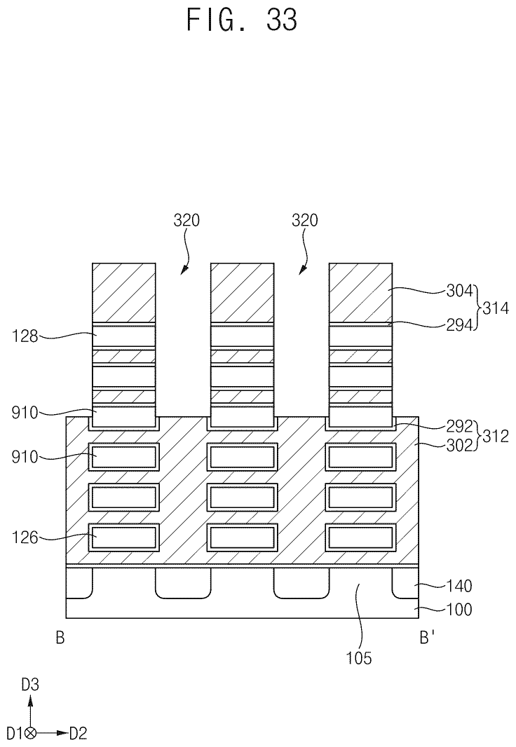

Referring to FIGS. 32 and 33, an upper portion of the gate structure 310 may be partially removed by, e.g., a dry etching process to form a first recess 320.

In some implementations, an upper portion of a portion of the gate structure 310 between ones of the first stack structures neighboring in the second direction D2 by the dry etching process may be removed, and thus opposite sidewalls in the second direction D2 of the semiconductor patterns 124 included in an upper portion of each of the first stack structures, and opposite sidewalls in the second direction D2 of the semiconductor patterns 124 spaced apart from each other in the third direction D3 may be exposed by the first recess 320.

In some implementations, an upper surface of a lower portion of the gate structure 310 remaining after the dry etching process is higher than or substantially coplanar with a lower surface of an upper one of the first insulation patterns 910, and may be lower than or substantially coplanar with an upper surface of the upper one of the first insulation patterns 910. Hereinafter, the lower portion of the gate structure 310 may be referred to as a first gate structure 312, and the first gate structure 312 may include a first gate electrode 302 and a first gate insulation pattern 292.

A portion of the gate structure 310 remaining at a level of the first recess 320 after the dry etching process may be referred to as a second gate structure 314, and the second gate structure 314 may include a second gate electrode 304 and a second gate insulation pattern 294.

Lower ones of the semiconductor patterns 124 extending through the first gate structure 312 may be referred to as first semiconductor patterns 126, and upper ones of the semiconductor patterns 124 may be referred to as second semiconductor patterns 128.

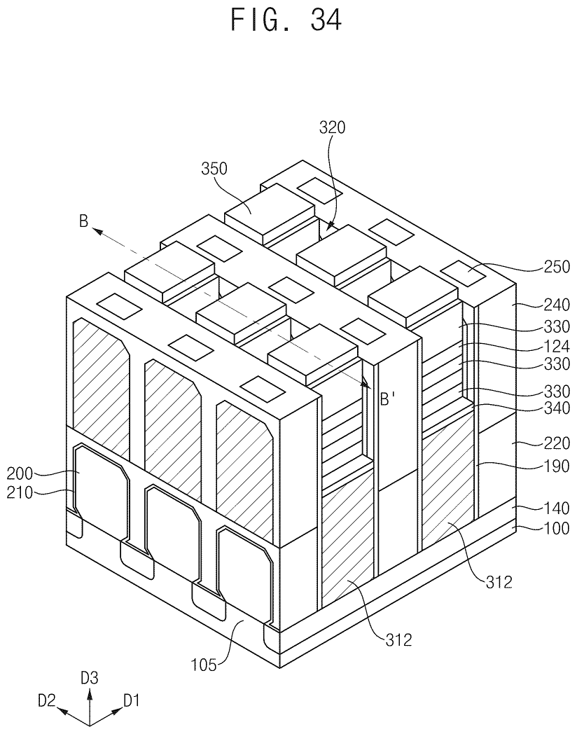

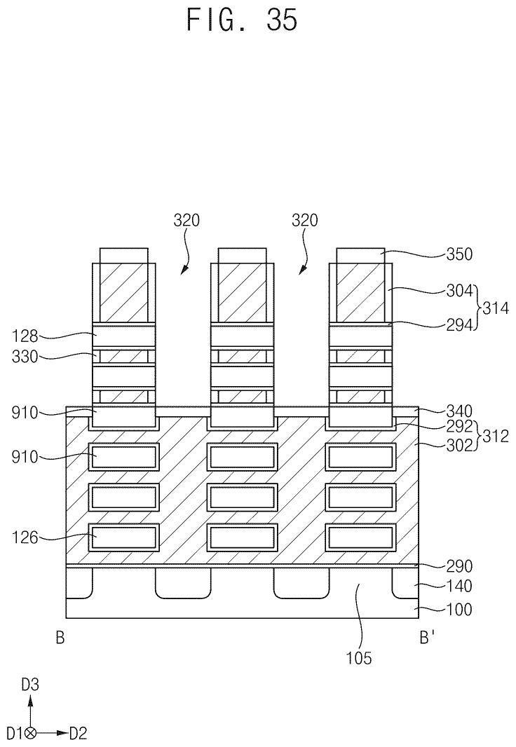

Referring to FIGS. 34 and 35, the opposite sidewalls in the second direction D2 of the second gate electrode 304 exposed by the first recess 320 may be partially removed to form a second recess, and an inner spacer 330 may be formed in the second recess.

The inner spacer 330 may be formed by forming an inner spacer layer on the first and second gate structures 312 and 314, the second insulating interlayer pattern 240 and the sixth sacrificial pattern 250, and performing, e.g., a wet etching process on the inner spacer layer.

A selective deposition process may be performed on upper surfaces of the first and second gate electrodes 302 and 304 included in the first and second gate structures 312 and 314, respectively, which are exposed by the first recess 320, to form second and third capping patterns 340 and 350, respectively.

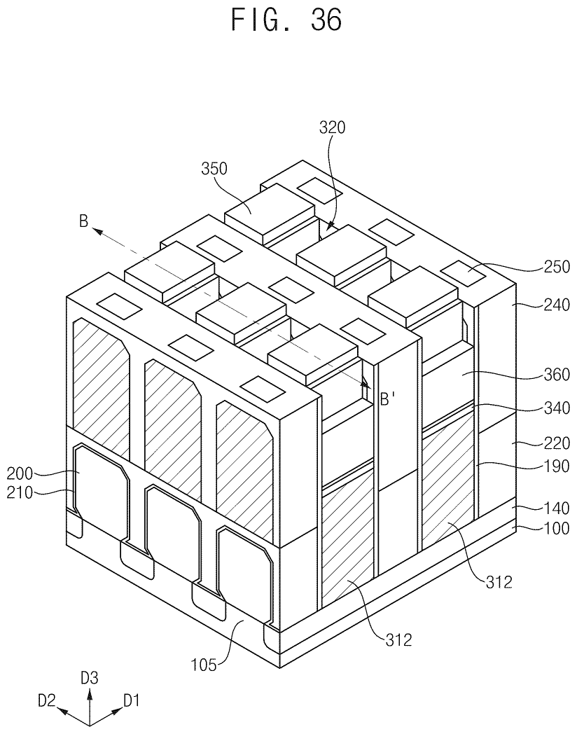

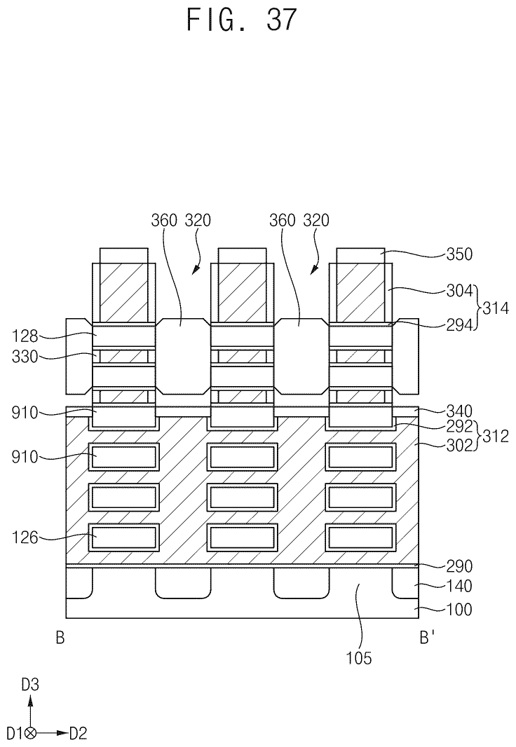

Referring to FIGS. 36 and 37, a third SEG process may be performed using opposite sidewalls in the second direction D2 of the second semiconductor patterns 128 exposed by the first recess 320 as a seed to form a second source/drain layer 360.

In some implementations, the third SEG process is performed using a silicon source gas, e.g., disilane (Si₂H₆) gas, a carbon source gas, e.g., SiH₃CH₃, and an n-type impurity source gas, e.g., phosphine (PH₃) gas, and thus the second source/drain layer 360 may be formed to include a single crystalline silicon carbide doped with n-type impurities.

In some implementations, the third SEG process is performed using the silicon source gas, e.g., disilane (Si₂H₆) gas and the n-type impurity source gas, e.g., phosphine (PH₃) gas, and thus the second source/drain layer 360 may be formed to include a single crystalline silicon doped with n-type impurities.

In some implementations, a lower surface of the second source/drain layer 360 is higher than or substantially coplanar with an upper surface of the second capping pattern 340, and an upper surface of the second source/drain layer 360 may be higher than or substantially coplanar with an upper surface of an uppermost one of the second semiconductor patterns 128.

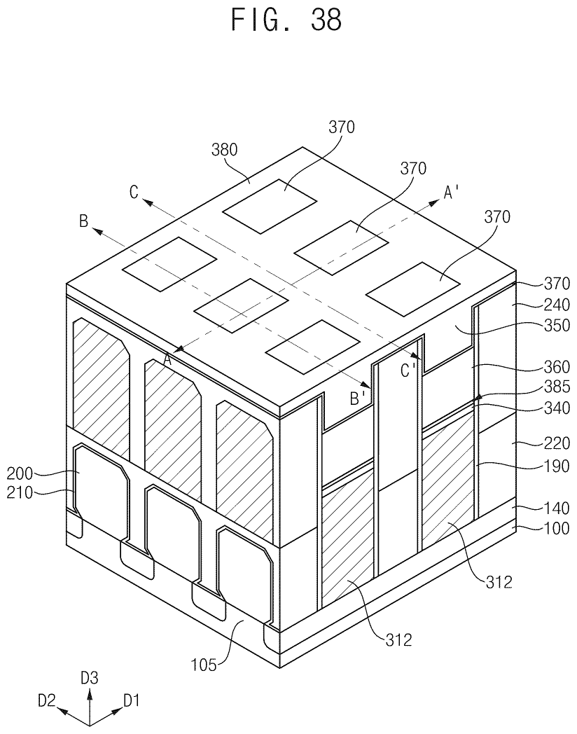

Referring to FIGS. 38 to 41, an etch stop layer 370 may be formed on the upper surface of the second source/drain layer 360, a sidewall and an upper surface of the third capping pattern 350, the upper surface of the second insulating interlayer pattern 240 and the upper surface of the sixth sacrificial pattern 250, a third insulating interlayer may be formed on the etch stop layer 370, and a planarization process may be performed on the third insulating interlayer until an upper surface of a portion of the etch stop layer 370 on the upper surface of the third capping pattern 350 is exposed to form a third insulating interlayer pattern 380.

In some implementations, the etch stop layer 370 and the third insulating interlayer may not be formed between the second capping pattern 340 on the upper surface of the first gate structure 312 and the second source/drain layer 360, so that an air gap 385 may be formed.

Referring back to FIGS. 1 to 8, the third insulating interlayer pattern 380 and the etch stop layer 370 may be partially removed to expose the upper surface of the sixth sacrificial pattern 250, the sixth sacrificial pattern 250 may be removed by, e.g., a wet etching process to form a sixth opening, a second insulation pattern 390 may be formed on a sidewall of the sixth opening, and a first contact plug 400 may be formed to fill a remaining portion of the sixth opening.

Additionally, the third insulating interlayer pattern 380 and the etch stop layer 370 may be partially removed to form a seventh opening exposing the upper surface of the second source/drain layer 360, and a second contact plug 410 may be formed in the seventh opening. The etch stop layer 370 and the third capping pattern 350 may be partially removed to form an eighth opening exposing the upper surface of the second gate electrode 304, and a third contact plug 420 may be formed in the eighth opening.

Upper wirings may be formed to be electrically connected to the first to third contact plugs 400, 410 and 420 so that the semiconductor device may be manufactured.

In some implementations, a fourth contact plug contacting the first gate electrode 302 and lower wirings electrically connected to the fourth contact plug is formed.

As illustrated above, the first semiconductor patterns 126, the first insulation patterns 910 and the second semiconductor patterns 128 may be sequentially stacked on the substrate 100, the dummy gate structure 180 may be formed on the substrate 100 to cover the first insulation patterns 910 and the second semiconductor patterns 128, the first source/drain layer 200 may be formed by the first SEG process on each of opposite lower sidewalls in the first direction D1 of the dummy gate structure 180, the fifth sacrificial layer 230 may be formed by the second SEG process on each of upper sidewalls in the first direction D1 of the dummy gate structure 180, the sixth sacrificial pattern 250 may be formed through the fifth sacrificial layer 230 to the upper surface of the first source/drain layer 200, the dummy gate structure 180 and the fifth sacrificial layer 230 may be removed to form the third to fifth openings 260, 270 and 280, and the gate structure 310 may be formed to fill the third to fifth openings 260, 270 and 280.

The upper portion of the gate structure 310 may be removed to form the first and second gate structures 312 and 314, the second source/drain layer 360 may be formed by the third SEG process on each of opposite sidewalls in the second direction D2 of the second gate structure 314, the sixth sacrificial pattern 250 may be replaced by the first contact plug 400, and the second and third contact plugs 410 and 420 may be formed to complete the fabrication of the semiconductor device.

Thus, the first contact plug 400 contacting the first source/drain layer 200 to be electrically connected thereto may be formed relatively simply, e.g., even without forming an additional structure detouring the second source/drain layer 360.

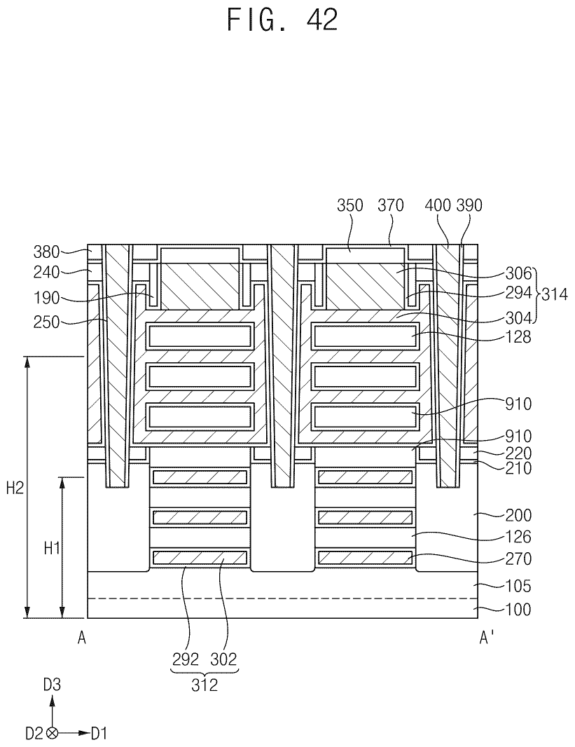

FIG. 42 is a cross-sectional view illustrating another example of a semiconductor device, with a view corresponding to that of FIG. 3. This semiconductor device may be substantially the same as or similar to that of FIGS. 1 to 8, except where noted otherwise or suggested otherwise by context (e.g., in reference to the second gate structure), and thus repeated explanations are omitted herein.

Referring to FIG. 42, the second gate electrode included in the upper portion of the second gate structure 314 may include a first portion 304 and a second portion 306 stacked in the third direction D3, which may include different materials from each other.

For example, a portion 306 of the upper portion of the second gate structure 314 having at least a portion higher than the vertical extension of the second gate structure 314 may include a metal, e.g., molybdenum, tungsten, etc., and other portions 304 of the second gate structure 314 may include a metal compound, e.g., titanium nitride, titanium aluminum carbide, etc.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of examples and is not to be construed as limiting thereof. Although a few examples have been described, those skilled in the art will readily appreciate that many modifications are possible without materially departing from the novel teachings and advantages of the present disclosure. Accordingly, all such modifications are intended to be included within the scope of the disclosure. In the claims, means-plus-function clauses are intended to cover the structures described herein as performing the recited function and not only structural equivalents but also equivalent structures. Therefore, it is to be understood that the foregoing is illustrative of various examples and is not to be construed as limited to the specific examples disclosed, and that modifications to the disclosed examples, as well as other implementations, are intended to be included within the scope of the present disclosure.

What is claimed is:

1. A semiconductor device, comprising:
a first transistor including:
a plurality of first channels on a substrate, the plurality of first channels spaced apart from each other in a vertical direction substantially perpendicular to an upper surface of the substrate;
a first gate structure extending on the substrate in a first direction substantially parallel to the upper surface of the substrate, wherein the first gate structure covers upper and lower surfaces of the plurality of first channels, and covers sidewalls, opposite to one another in the first direction, of the plurality of first channels; and
a pair of first source/drain layers at opposite sides of the first gate structure in a second direction substantially parallel to the upper surface of the substrate and substantially perpendicular to the first direction;
a second transistor including:
a plurality of second channels on the first channels, the second channels spaced apart from each other in the vertical direction;
a second gate structure extending on the substrate in the second direction, wherein the second gate structure covers upper and lower surfaces of the plurality of second channels, and covers sidewalls, opposite to one another in the second direction, of the plurality of second channels; and
a pair of second source/drain layers at opposite sides of the second gate structure in the first direction; and
a contact plug extending in the vertical direction and contacting an upper surface of each of the pair of first source/drain layers.

2. The semiconductor device of claim 1, wherein the plurality of first channels overlap the plurality of second channels along the vertical direction.

3. The semiconductor device of claim 1, wherein the plurality of first channels and the plurality of second channels have substantially the same shape and size.

4. The semiconductor device of claim 1, wherein the pair of second source/drain layers is non-overlapping with the pair of first source/drain layers along the vertical direction.

5. The semiconductor device of claim 1, wherein the pair of first source/drain layers is doped with impurities of a first conductivity type, and the pair of second source/drain layers is doped with impurities of a second conductivity type.

6. The semiconductor device of claim 5, wherein the pair of first source/drain layers comprises single crystalline silicon-germanium doped with p-type impurities, and the pair of second source/drain layers comprises single crystalline silicon or silicon carbide doped with n-type impurities.

7. The semiconductor device of claim 1, further comprising a plurality of insulation patterns between and spaced apart from the plurality of first channels and the plurality of second channels, wherein the plurality of insulation patterns are aligned with the plurality of first channels and the plurality of second channels along the vertical direction and are spaced apart from each other along the vertical direction.

8. The semiconductor device of claim 7, wherein an upper surface of the first gate structure is higher than or substantially coplanar with a lower surface of an uppermost one of the plurality of insulation patterns.

9. The semiconductor device of claim 7, wherein an upper surface of the first gate structure is lower than or substantially coplanar with an upper surface of a lowermost one of the plurality of insulation patterns.

10. The semiconductor device of claim 1, wherein the second gate structure includes:
a plurality of first portions overlapping the plurality of second channels along the vertical direction; and
a pair of second portions extending in the vertical direction and contacting sidewalls, opposite to one another in the second direction, of the plurality of first portions.

11. A semiconductor device, comprising:
a plurality of first channels on a substrate, the plurality of first channels spaced apart from each other in a vertical direction substantially perpendicular to an upper surface of the substrate;
a first gate structure extending on the substrate in a first direction substantially parallel to the upper surface of the substrate, wherein the first gate structure covers upper and lower surfaces of the plurality of first channels and covers sidewalls, opposite to one another in the first direction, of the plurality of first channels;
a pair of first source/drain layers at opposite sides of the first gate structure in a second direction substantially parallel to the upper surface of the substrate and substantially perpendicular to the first direction;
a plurality of second channels on the plurality of first channels, the plurality of second channels spaced apart from each other in the vertical direction;
a second gate structure extending on the substrate in the second direction, wherein the second gate structure covers upper and lower surfaces of the plurality of second channels and covers sidewalls, opposite to one another in the second direction, of the second channels;
a pair of second source/drain layers at opposite sides of the second gate structure in the first direction; and
a contact plug extending in the vertical direction through the second gate structure, wherein the contact plug is insulated from the second gate structure and contacts an upper surface of each of the pair of first source/drain layers.

12. The semiconductor device of claim 11, further comprising a plug insulation pattern covering a sidewall of the contact plug and contacting the second gate structure.

13. The semiconductor device of claim 12, wherein the second gate structure includes a gate insulation pattern and a gate electrode, and
wherein the gate insulation pattern contacts the plug insulation pattern, and wherein the gate electrode is spaced apart from the plug insulation pattern.

14. The semiconductor device of claim 11, wherein the plurality of first channels and the plurality of second channels have substantially the same shape and size, and overlap one another along the vertical direction.

15. The semiconductor device of claim 11, wherein the pair of second source/drain layers is non-overlapping with the pair of first source/drain layers along the vertical direction.

16. The semiconductor device of claim 11, further comprising a plurality of insulation patterns between and spaced apart from the plurality of first channels and the plurality of second channels, wherein the insulation patterns overlap the plurality of first channels and the plurality of second channels along the vertical direction and are spaced apart from each other in the vertical direction.

17. The semiconductor device of claim 16, wherein an upper surface of a first portion of the first gate structure is higher than or substantially coplanar with a lower surface of an uppermost one of the plurality of insulation patterns, and
wherein an upper surface of a second portion of the first gate structure is lower than or substantially coplanar with an upper surface of a lowermost one of the plurality of insulation patterns.

18. A semiconductor device, comprising:
a first transistor including:
a plurality of first channels on a substrate, the plurality of first channels spaced apart from each other in a vertical direction substantially perpendicular to an upper surface of the substrate;
a first gate structure extending on the substrate in a first direction substantially parallel to the upper surface of the substrate, wherein the first gate structure covers upper and lower surfaces of the plurality of first channels and covers sidewalls, opposite to one another in the first direction, of the plurality of first channels; and
a pair of first source/drain layers at opposite sides of the first gate structure in a second direction substantially parallel to the upper surface of the substrate and substantially perpendicular to the first direction;
a second transistor including:
a plurality of second channels on the first channels, the second channels spaced apart from each other in the vertical direction;
a second gate structure extending on the substrate in the second direction, wherein the second gate structure covers upper and lower surfaces of the plurality of second channels and covers sidewalls, opposite to one another in the second direction, of the plurality of second channels; and
a pair of second source/drain layers at opposite sides of the second gate structure in the first direction;
a plurality of insulation patterns between and spaced apart from the plurality of first channels and the plurality of second channels, wherein the insulation patterns overlap the plurality of first channels and the plurality of second channels along the vertical direction and are spaced apart from each other in the vertical direction;
a first contact plug extending in the vertical direction and contacting an upper surface of each of the pair of first source/drain layers;
a second contact plug contacting an upper surface of each of the pair of second source/drain layers; and
a third contact plug contacting an upper surface of the second gate structure.

19. The semiconductor device of claim 18, wherein an upper surface of a first portion of the first gate structure is higher than or substantially coplanar with a lower surface of an uppermost one of the plurality of insulation patterns, and
wherein an upper surface of a second portion of the first gate structure is lower than or substantially coplanar with an upper surface of a lowermost one of the plurality of insulation patterns.

20. The semiconductor device of claim 18, wherein the first contact plug extends through the second gate structure and is insulated from the second gate structure.
